(19) United States
(12) Patent Application Publication
(10) Pub. No.: US 2015/0009556 A1
(43) Pub. Date: Jan. 8, 2015

(54) OPTICAL ELEMENT, OPTICAL THIN FILM FORMING APPARATUS, AND OPTICAL THIN FILM FORMING METHOD

(71) Applicant: HOYA CORPORATION, Tokyo (JP)

(72) Inventors: Shuichiro Kawagishi, Tokyo (JP); Teruo Yamashita, Tokyo (JP)

(21) Appl. No.: 14/369,833

(22) PCT Filed: Dec. 28, 2012
(86) PCT No.: PCT/JP2012/084172

§ 371 Date: Aug. 29, 2014

(30) Foreign Application Priority Data
Dec. 30, 2011 (JP) 2011-290468

(51) Int. Cl. G02B 1/11; C23C 14/34; G02B 3/04

(52) U.S. Cl. CPC G02B 1/11; G02B 3/04; C23C 14/34
USPC 359/350; 359/589; 204/192.26; 204/298.07

(57) ABSTRACT

In forming an optical thin film on a curved surface of a material to be deposited, a specific space, which is part of a space in a processing chamber and is a space between an arrangement part and a target, is surrounded by a shielding part. In this state, when deposition is performed by a sputtering step in which a voltage is applied to the target in the processing chamber which is in a vacuum state and supplied with an active gas and an inert gas, an optical thin film of a substantially equal optical thickness is formed on the curved surface.

### TECHNICAL FIELD

The present invention relates to an optical element on which an optical thin film is formed on a curved surface of a material to be deposited such as a curved substrate and an optical lens, an optical thin film forming apparatus for forming such an optical thin film, and an optical thin film forming method.

### BACKGROUND ART

Antireflection coatings are known as a kind of optical thin film, for instance. A multilayered antireflection coating is provided on surfaces of imaging lenses integrated in a digital camera, projection lenses integrated in a liquid crystal projector, and a cover glass and such of an optical instrument in order to reduce transmitted light quantity loss and prevent ghost, flare, and such from occurring. The antireflection coating needs to be deposited so as not to generate any optical thickness distribution such that predetermined antireflection characteristics can be obtained. When forming an antireflection coating on a lens surface, since the lens surface is a curved surface of a convex shape or a concave shape, which is different from the case where a film is formed on a flat surface such as an ordinary planar substrate, a physical thickness distribution is likely to occur between a center of the lens surface and the periphery thereof. For instance, when depositing a film on a concave surface of a concave meniscus lens used for a camera lens, a film is less likely to be deposited at the peripheral part, and a physical thickness thereof is likely to be thinner than that at the center part. Because of this, a difference in reflectance exceeding an acceptable range is likely to be generated between the center part of the lens surface and the periphery thereof.

In PTL 1 (Japanese Patent Application Laid-open No. 2011-84760) a film forming method is proposed for forming an antireflection coating on a concave lens surface using a sputtering method. The film forming method aims at improving a film thickness distribution of an antireflection coating and such deposited on a concave surface lens of a small radius of curvature and is configured to deposit a thin film of a uniform film thickness on a concave spherical surface of a concave surface lens by a sputtering method through a mask for film thickness adjustment arranged between the target and a concave spherical surface. The film forming method is configured to prevent a shade from being generate at a center part of the lens and improve film thickness unevenness of an antireflection coating and such deposited on a concave surface lens of a small radius of curvature by adjusting an aperture diameter and a position of a circular aperture of a mask (PTL 1: paragraphs 0008 to 0010 of Japanese Patent Application Laid-open No. 2011-84760).

### CITATION LIST

### Patent Literature

[PTL 1]

Japanese Patent Application Laid-open No. 2011-84760

### SUMMARY OF INVENTION

### Technical Problem

In recent years, optical performance required for optical systems has become high, further improvement in performance of an optical thin film such as an antireflection coating is demanded. Also, as lens diameters are increased and field angles are widened, concave surface lenses, convex surface lenses, aspherical lenses, and free curved surface lenses of smaller radiuses of curvature are widely used.

For instance, an aspherical lens of a concave meniscus shape having a maximum surface angle of a concave surface of 40° or more is used for a high performance digital camera lens. In an antireflection coating formed on a concave lens surface having such a large maximum surface angle, when there is a film thickness distribution between a center part of the lens and a peripheral part, a ghost is likely to be generated in a photographed image due to a reflectance difference caused thereby. The ghost largely influences on camera lens system performance and optical lens design, which is not preferable.

In PTL 1 mentioned above, when depositing an antireflection coating on a concave surface lens, since a mask for film thickness adjustment must be provided, it is difficult to form an antireflection coating at the same time across the entire lens surface to be deposited and difficult to sufficiently suppress a film thickness variation.

At a portion where a surface angle changes, especially at a peripheral part of the surface where the surface angle largely changes, since a ray angle to a lens surface becomes large, intensity of reflected light becomes strong, reflected light concentrates at part of an imaging plane to be a ghost, and quality of a captured image may be significantly degraded. Therefore, it is necessary to make a film thickness distribution more uniform. However, since with the conventional film forming method an optical multilayer film cannot be deposited with an equal optical thickness up to the peripheral part, it is difficult to deposit with a uniform film thickness distribution especially at a peripheral part of a surface where a surface angle becomes large.

As described above, with the method using the sputtering method in PTL 1 configured to deposit a film on a curved surface such as a lens surface, it is difficult to form an optical thin film having an optical thickness substantially equal across the entire lens surface. Also, with the film forming method in PTL 1, when depositing films on a plurality of lenses, it is also difficult to obtain optical thin films having no variation in optical thicknesses between lenses.

The above mentioned problem exists concerning a material to be deposited other than a lens such as, for instance, a curved surface type mirror (a reflection type optical element), a curved surface type filter, an array shaped optical element (a lens array and a prism array), a finder element, a diffraction type optical element, and a Fresnel lens.

The objective of one embodiment of the present invention is to provide an optical element on which an optical thin film having a substantially equal optical thickness over the entire area of a curved surface of a material to be deposited is formed. Another objective of one embodiment of the present invention is to provide an optical thin film forming apparatus and an optical thin film forming method, capable of forming an optical thin film whose optical thickness is substantially equal over the entire area of a curved surface of a material to be deposited.

### Solution to Problem

An optical element in accordance with one embodiment of the present invention includes: a curved surface formed in a curved shape; and an optical thin film formed on the curved surface. The curved surface includes: a first area including a center of the curved surface; and a second area separated from the first area. An optical thickness of an optical thin film on the first area and an optical thickness of an optical thin film on the second area are substantially equal.

An optical thin film forming apparatus in accordance with one embodiment of the present invention is an apparatus that includes a processing chamber and is configured to form an optical thin film on a material to be deposited having a curved surface in the processing chamber. The apparatus includes: an exhaust part that is configured to exhaust air in the processing chamber; and a gas supply part that is configured to supply an active gas and an inert gas into the processing chamber that is retained in a vacuum state. The apparatus also includes: an arrangement part which is provided in the processing chamber and on which a material to be deposited is arranged; and a target arranged opposite to the arrangement part in the processing chamber. The apparatus further includes: a power supply that is configured to apply a voltage to the target so as to emit target particles; and a shielding part provided in the processing chamber and configured to be capable of surrounding a specific space, which is part of a space in the processing chamber and is a space between the target and the arrangement part.

An optical thin film forming method in accordance with one embodiment of the present invention is a method for forming an optical thin film on a material to be deposited having a curved surface. The method includes: an arrangement step of arranging the material to be deposited on an arrangement part in a processing chamber; and an evacuating step of evacuating an inside of the processing chamber in a state where the material to be deposited is arranged in the processing chamber. The method also includes a gas supply step of supplying an active gas and an inert gas into the processing chamber after evacuation. The method also includes a sputtering step of emitting target particles from a target provided in the processing chamber and arranged opposite to the arrangement part by applying a voltage to the target to cause the inert gas to collide with the target. The method further includes an optical thin film forming step of depositing the target particles obtained by the sputtering step or particles reacting with the active gas on the curved surface of the material to be deposited in a state where a specific space that is part of a space in the processing chamber and is a space between the target and the arrangement part is surrounded by a shielding part.

### Advantageous Effects of Invention

Since an optical element in accordance with one embodiment of the present invention includes an optical thin film having an optical thickness substantially equal over the entire area of a curved surface, it is expected that optical characteristics are substantially equal, or uniform.

The apparatus and the method in accordance with one embodiment of the present invention is capable of forming an optical thin film having an optical thickness substantially equal over the entire area of the curved surface of the material to be deposited.

### BRIEF DESCRIPTION OF DRAWINGS

FIG. 1 is a conceptual diagram of a reactive sputtering apparatus in accordance with one embodiment of the present invention.

FIG. 2 is a view illustrating how target particles in a processing chamber of a reactive sputtering apparatus of FIG. 1 are deposited on lenses.

FIG. 3 is a view illustrating a configuration example of an optical lens in accordance with one embodiment of the present invention and how target particles are deposited on an optical lens in one embodiment of the present invention.

FIG. 4 is a view illustrating a measurement area of reflectance at a lens surface in accordance with one embodiment of the present invention.

FIG. 5 is a table showing a film constitution of an antireflection coating in Example 1 and film forming conditions by a reactive sputtering.

FIG. 6 is a cross section illustrating a lens surface of an optical lens which is a target to be deposited in Example 1 and a diagram showing spectral reflectance characteristics of an antireflection coating formed on the lens surface.

FIG. 7 is diagrams showing spectral reflectance characteristics of an antireflection coating at part of measurement positions on the lens surface of the optical lens that is a target to be deposited in Example 1.

FIG. 8 is a table showing a film constitution of an antireflection coating in Example 2 and film forming conditions by a reactive sputtering.

FIG. 9 is a cross section illustrating a lens surface of an optical lens which is a target to be deposited in Example 2 and a diagram showing spectral reflectance characteristics of an antireflection coating formed on the lens surface.

FIG. 10 is diagrams showing spectral reflectance characteristics of an antireflection coating at part of measurement positions on the lens surface of the optical lens that is a target to be deposited in Example 2.

FIG. 11 is a table showing a film constitution of an antireflection coating in Example 3 and film forming conditions by a reactive sputtering.

FIG. 12 is a cross section illustrating a lens surface of an optical lens which is a target to be deposited in Example 3 and a diagram showing spectral reflectance characteristics of an antireflection coating formed on the lens surface.

FIG. 13 is diagrams showing spectral reflectance characteristics of an antireflection coating at part of measurement positions on the lens surface of the optical lens that is a target to be deposited in Example 3.

FIG. 14 is a table showing a film constitution of an antireflection coating in Example 4 and film forming conditions by a reactive sputtering.

FIG. 15 is a cross section illustrating a lens surface of an optical lens which is a target to be deposited in Example 4 and a diagram showing spectral reflectance characteristics of an antireflection coating formed on the lens surface.

FIG. 16 is a diagram showing spectral reflectance characteristics of an antireflection coating at part of measurement positions arranged in a radial direction on the lens surface of the optical lens that is a target to be deposited in Example 4.

FIG. 17 is a table showing a film constitution of an antireflection coating in Example 5 and film forming conditions by a reactive sputtering.

FIG. 18 is a cross section illustrating a lens surface of an optical lens which is a target to be deposited in Example 5 and a diagram showing spectral reflectance characteristics of an antireflection coating formed on the lens surface.

FIG. 19 is diagrams showing spectral reflectance characteristics of an antireflection coating at part of measurement positions on the lens surface of the optical lens that is a target to be deposited in Example 5.

FIG. 20 is a table showing a film constitution of an antireflection coating in Example 6 and film forming conditions by a reactive sputtering.

FIG. 21 is a cross section illustrating a lens surface of an optical lens which is a target to be deposited in Example 6 and a diagram showing spectral reflectance characteristics of an antireflection coating formed on the lens surface.

FIG. 22 is diagrams showing spectral reflectance characteristics of an antireflection coating at part of measurement positions on the lens surface of the optical lens that is a target to be deposited in Example 6.

FIG. 23 is a table showing a film constitution of an antireflection coating in Comparative example 1 and film forming conditions by an evaporation method.

FIG. 24 is a cross section illustrating a lens surface of an optical lens which is a target to be deposited in Comparative example 1 and a diagram showing spectral reflectance characteristics of an antireflection coating formed on the lens surface.

FIG. 25 is diagrams showing spectral reflectance characteristics of an antireflection coating at part of measurement positions on the lens surface of the optical lens that is a target to be deposited in Comparative example 1.

FIG. 26 is a table showing a film constitution of an antireflection coating in Comparative example 2 and film forming conditions by a sputtering method.

FIG. 27 is a cross section illustrating a lens surface of an optical lens which is a target to be deposited in Comparative example 2 and a diagram showing spectral reflectance characteristics of an antireflection coating formed on the lens surface.

FIG. 28 is diagrams showing spectral reflectance characteristics of an antireflection coating at part of measurement positions on the lens surface of the optical lens that is a target to be deposited in Comparative example 2.

### DESCRIPTION OF EMBODIMENTS

Embodiments of the present invention will be described below. Embodiments that are described below do not restrict the inventions related to the claims and various elements described in the embodiments and all combinations thereof are not necessarily indispensable to solutions to problems of the inventions.

In the description below, “optical thickness is substantially uniform or substantially equal” means that, at a predetermined value of spectral characteristics (Here, a description is made by taking spectral reflectance of an antireflection coating as an example. In general, “spectral reflectance” is a term for reflectance represented as a function of wavelength (NPL: “an optical glossary P237, publisher: Ohm-Sha). In the present description, “spectral reflectance” is also referred to as “spectral reflectance characteristics” or “characteristic curve”.) of an optical thin film, a wavelength difference is small between a center position of a lens and a peripheral part, specifically, within a range of a predetermined value, where an optical thickness is represented by a product of refractive index n and a physical thickness d.

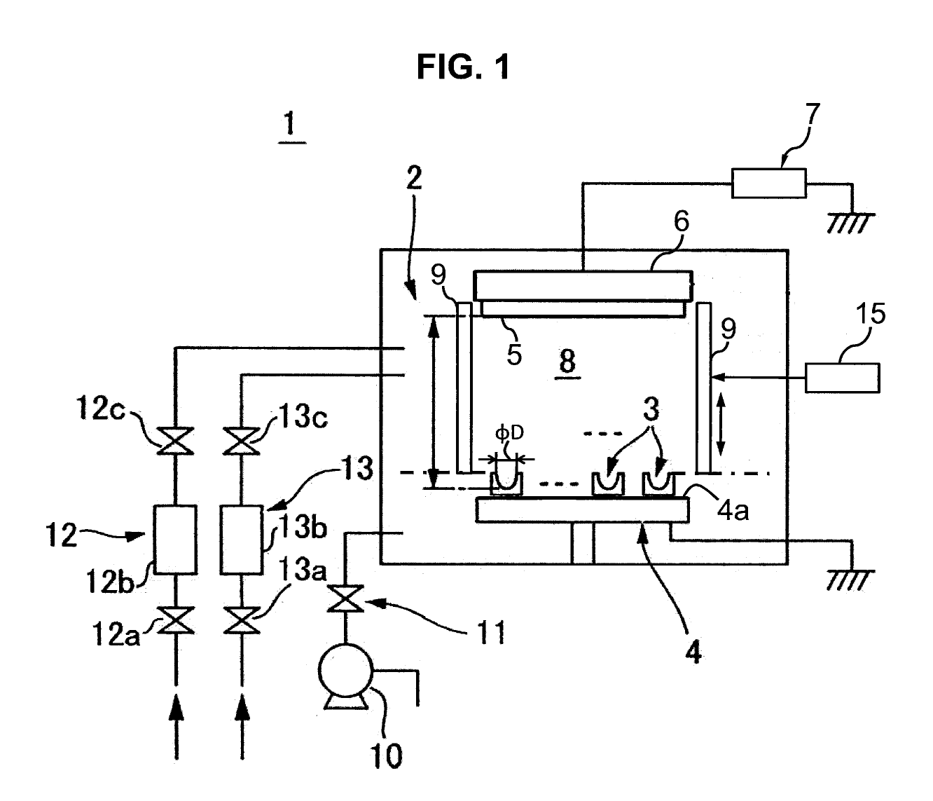

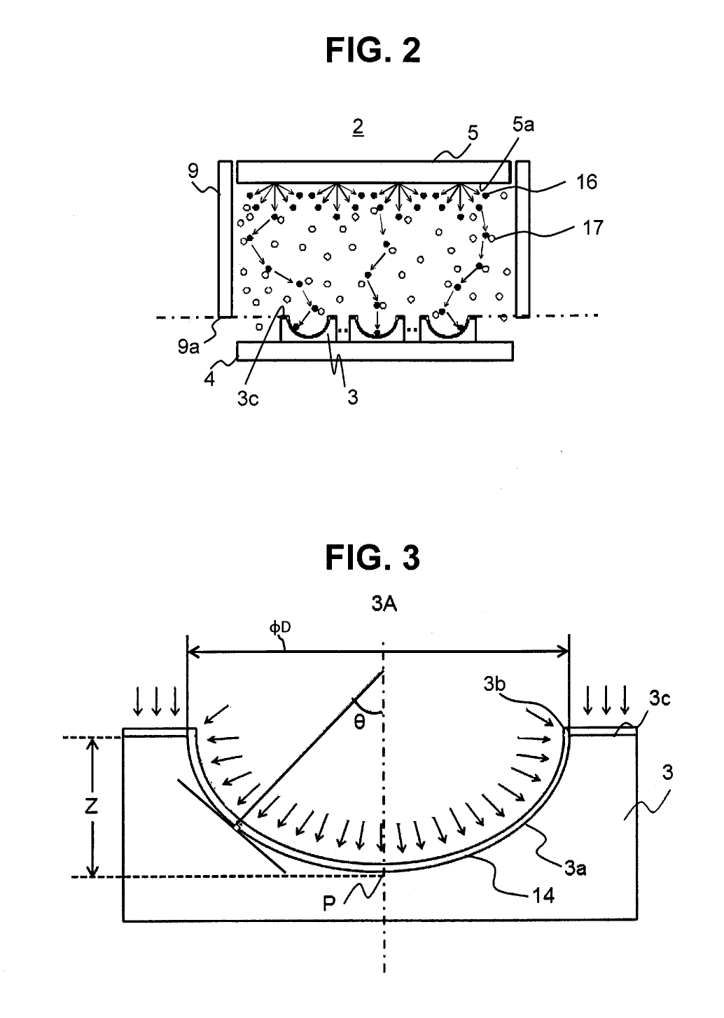

FIG. 1 is a conceptual diagram of a reactive sputtering apparatus in accordance with one embodiment of the present invention, FIG. 2 is a view illustrating how target particles in a processing chamber of a reactive sputtering apparatus of FIG. 1 are being deposited on a lens, and FIG. 3 is a view illustrating a configuration example of an optical lens in accordance with one embodiment of the present invention and how target particles are deposited on an optical lens in one embodiment of the present invention.

A description is made below by referring to FIGS. 1 to 3. A reactive sputtering apparatus 1 includes a processing chamber 2 capable of forming a predetermined vacuum state. A workpiece holder 4 for mounting optical lenses 3 (workpieces) that are a target to be deposited is arranged in the processing chamber 2. One or a plurality of optical lenses 3 are arranged on a workpiece mounting surface 4a of the workpiece holder 4. A target 5 configured to sputter is arranged in parallel, facing to the workpiece mounting surface 4a, separated by a constant distance. An electrode, for instance, a sputtering electrode 6, is arranged on a back surface of the target 5, and a voltage is applied to the sputtering electrode 6 from, for instance, a power supply 7.

A specific space 8, which is a space between the target 5 and the workpiece mounting surface 4a, is part of a space in a space of the processing chamber 2. The reactive sputtering apparatus 1 includes a shielding part 9 that is capable of surrounding a neighborhood of the specific space 8, which is a range, here, in a direction perpendicular to a direction heading the workpiece holder 4 from the target 5.

The shielding part 9 is capable of surrounding the whole or a large fraction of the circumference of the specific space 8. The shielding part 9 may be a cylindrical member constituted of a folded or a bent sheet, and may be a member constituted of a combination of a plurality of members (for instance, an arc-shaped or a tabular member). A material of the shielding part 9 is preferably made of SUS or ceramics.

A position of a lowest part 9a (an end part on the workpiece mounting surface 4a side) of the shielding part 9 is a position which is at the same height as a highest surface (a top surface of the optical lenses 3 in FIG. 1) of the optical lenses 3 arranged on the workpiece holder 4 on the target 5 side or at a position lower than that. Because of this, the specific space 8, particularly, a space from the top surface of the optical lenses 3 to a surface 5a of the target 5, is shielded from a space in the neighborhood of the specific space 8 in the processing chamber 2. The specific space 8 is an enclosed space. By taking such a configuration, diffusion of target atoms or compound particles from the specific space 8 to the neighborhood may be suppressed, concentration (density) of plasma in the specific space 8 composed of a material including an introduction gas such as Ar gas or O₂ gas and ions such as Ar ions or oxygen ions may be increased, and the plasma may be uniformly distributed when plasma concentration is increased. In the specific space 8, a viscous flow domain of the target atoms and the compound particles may be formed, and an antireflection coating of a substantially uniform optical thickness may be formed over the whole area of aspherical lens surfaces 3a of the optical lenses 3.

The reactive sputtering apparatus 1 also includes a position change part 15. The position change part 15 performs at least one of a first change and a second change. The first change is to change a relative position of the shielding part 9 to the workpiece holder 4 from a first position, at which the shielding part 9 is configure to be capable of forming an enclosed space by surrounding the specific space 8 as shown in FIG. 1, in other words, an antireflection coatings 14 may be formed on the optical lenses 3 so that optical thickness distributions become a desired distribution, to a second position, at which, for instance, the shielding part 9 is relatively separated from the workpiece holder 4 to such an extent that at least one of operations of mounting the optical lenses 3 to the workpiece holder 4 and taking optical lenses 3 out of the workpiece holder 4 is possible. The second change is to change a relative position of the shielding part 9 to the workpiece holder 4 from the second position described above to the first position described above. In the embodiment, the position change part 15 is capable of performing both the first change described above and the second change described above by a method such as a method of vertically elevating or lowering the shielding part 9.

The processing chamber 2 is capable of evacuating with an exhaust mechanism 11 equipped with a vacuum pump 10. The processing chamber 2 is supplied with an inert gas such as an Ar gas from an inert gas supply mechanism 12 and supplied with an active gas such as an O₂ gas or an N₂ gas from an active gas supply mechanism 13. The inert gas supply mechanism 12 is configured to supply the processing chamber 2 with an inert gas through a valve 12a, a mass flow controller 12b, and a valve 12c from an unillustrated inert gas supply source. The active gas supply mechanism 13 is configured to supply the processing chamber 2 with an active gas through a valve 13a, a mass flow controller 13b, and a valve I3c from an unillustrated active gas supply source.

The optical lens 3, which is one example of a material to be deposited, is an aspherical concave lens, for instance, as illustrated in FIG. 3, and the concave shaped aspherical lens surface 3a is a curved surface, which is a target to be deposited. On the aspherical lens surface 3a, a multilayer antireflection coating 14, for instance, is formed by a film forming method of the present invention with reactive sputtering described above. The aspherical lens surface 3a is composed of an aspheric surface having a maximum surface angle θ of 40° or more, for instance. The surface angle θ is an angle between a normal line of the aspherical lens surface 3a and an optical axis 3A. An outer diameter of the peripheral edge 3b of the aspherical lens surface 3a is larger than a lens effective diameter. An annular land 3c of a constant width is continued in a direction orthogonal to the optical axis 3A to the peripheral edge 3b of the aspherical lens surface 3a. A spherical segment length Z of the optical lens 3 is a length in a direction along the optical axis 3A from a height position of the land 3c of the optical lens 3 to a height position of a center P of the optical lens 3.

In the optical thin film forming method in accordance with one embodiment of the present invention, in the processing chamber 2 where deposition is performed by reactive sputtering, relative positions of the workpiece holder 4 and the target 5 are configured so that the aspherical lens surface 3a of the optical lens 3 is positioned within a viscous flow domain where target particles, which are particles sputtered from the target 5 by plasma discharge and compound particles that are a compound of the particles and the active gas, scattered in the specific space 8 become a state of viscous flow. In other words, a height position, which is a distance between the target 5, of the workpiece mounting surface 4a of the workpiece holder 4 on which the optical lenses 3 are mounted is configured so that the aspherical lens surfaces 3a of the optical lenses 3 are positioned within the viscous flow domain. The state of viscous flow is a state in which collisions of particles occupies the most part, pressure is high, and a mean free path is short. For instance, the optical lenses 3 are arranged in a domain where Knudsen number, which is obtained by a ratio between the mean free path of the target particles and a distance between inside surfaces of the shielding part 9, is less than 0.01. The workpiece holder 4 and the target 5 are arranged so that, in a state where the optical lenses 3 are arranged on the workpiece holder 4, a value that is obtained by dividing, by a distance L from the target 5 surface to the farthest position of the concave surface shapes of the optical lenses 3, a value that is obtained by further dividing a surface diameter D of the curved surface by a spherical segment length Z of the concave surface shape falls within a range between 0.010 and 10.

In a film deposition operation by reactive sputtering in the reactive sputtering apparatus 1, as illustrated in FIG. 2, after the optical lenses 3, which are targets to be deposited, are mounted on the workpiece holder 4, the inside of the processing chamber 2 is maintained in a predetermined vacuum state, and the inert gas and the active gas are supplied into the processing chamber 2. By the inert gas atoms supplied in such a way, particles 16, which are the target original particles, are emitted, or sputtered, from the surface of the target 5. A sputtered target original particles 16 are repeatedly collided by target particles 16, which are at least one of other target original particles and compound particles, and by a gas particles 17, which is Ar particles, an O₂ particles, an Ar ion particles, or an O₂ ion particles, existing in the specific space 8. In the process, the target original particles 16 become compound particles, which are compound particles of oxide, by the active gas. The gas particles 17 are rebounded at the shielding part 9 when colliding with the shielding part 9, since the energy thereof is high. The compound particles 16 created in the process are adhered and deposited to the aspherical lens surfaces 3a of the optical lenses 3 to form optical thin films 14.

As illustrated in FIG. 2, in the optical thin film forming method in accordance with one embodiment of the present invention, a relative position of the workpiece holder 4 to the target 5 is determined so that the aspherical lens surfaces 3a of the optical lenses 3 are positioned within the viscous flow domain of the target particles, which are the target original particles and the compound particles. Within the viscous flow domain, the compound particles go around each part of the aspherical lens surfaces 3a of the optical lenses 3, and the particles almost uniformly collide from the normal directions with each part of the entire aspherical lens surfaces 3a from the center part to the peripheral part.

As a result, as described using FIG. 2, when compound particles 16 are deposited on the lens surface 3a, the antireflection coating 14 of a substantially uniform optical thickness is formed on the entire area of the aspherical lens surface 3a at each of the optical lenses 3 as illustrated in FIG. 3. When deposition is performed to a plurality of lens surfaces 3a of the optical lenses 3 at the same time, no substantial optical thickness variation exists among the plurality of optical lenses 3, and antireflection coatings 14 of substantially uniform optical thicknesses are formed on the plurality of optical lenses 3. In addition, also at a flat land 3c outside of the diameter of each of the lens surfaces, similar to the aspherical lens surfaces 3a, the antireflection coating 14 of a substantially equal, or uniform, optical thickness is formed to the end part of the land 3c. Although forming the film on such section does not influence on optical characteristics of each of the optical lenses 3 itself, when used as a lens, excellent effects are obtained such as improvements in influence caused by stray light incident on the land 3c and weather resistance of the antireflection coating 14 of each of the optical lenses 3. Also, in the present embodiment, the antireflection coating 14 whose optical thickness, a product of a physical thickness and refractive index, is substantially equal, or uniform, may be formed. The optical thicknesses of the antireflection coatings 14 are formed substantially equally across each of the optical lenses 3 and among the plurality of optical lenses 3.

To arrange the aspherical lens surfaces 3a of the optical lenses 3 within the viscous flow domain of the target atoms and the compound particles thereof, the aspherical lens surfaces 3a are arranged near the target 5. Specifically, it is desirable to configure a maximum distance L from the aspherical lens surfaces 3a to the surface 5a of the target 5 to be a value within a range of 0.1 mm to 200 mm. More specifically, it is desirable to configure a maximum distance L from the aspherical lens surfaces 3a to the surface 5a of the target 5 to be a value within a range of 30 mm to 50 mm. In the case of an aspherical concave lens illustrated in FIG. 1, a distance from the target surface 5a to the center position of the lens surface is the maximum distance L.

Although it is possible to arrange at a position closer than 0.1 mm, it is desirable to make the distance to be 0.1 mm or more, when considering contact of substrates, or lenses, and the target caused by thermal expansion during deposition, surface accuracy, or surface roughness, of the target surface, and machine precision of the deposition apparatus.

According to experiments made by the inventors of the present invention and such, when an optical thin film such as an antireflection coating is formed on a spherical convex lens surface, a spherical concave lens surface, an aspherical convex lens surface, and an aspherical concave lens surface of an optical lens 3, it is confirmed that it is desirable to form an antireflection coating according to film forming conditions shown in Table 1.

Specifically, by configuring the maximum distance L between the target surface 5a and the lens surfaces 3a of the optical lenses 3 within a range of 0.1 mm to 200 mm and depositing films by the present invention according to the film forming conditions shown in Table 1, and forming optical thin films composed of film materials of the constitution listed in Table 1, it is confirmed that optical thin films of optical thicknesses of substantially equal, or uniform, may be formed, as will be described later in Examples 1 to 6. Although in Table 1, conditions, or film forming conditions, for input power are described in a case of forming an SiO₂ thin film or an Nb₂O₅ thin film, in cases of other kinds of optical thin films, the input power may be in the same range as in the case of an SiO₂ thin film.

TABLE 1

| Refractive | | | Pressure | | |
|---|---|---|---|---|---|
| index | | Substrate | range | | |
| notation of | | heating | during | Deposition | |
| thin film | Target material | temperature | deposition | rate | Input power |
| M | Material including | A range | A range | A range | In the case of |
| | any of aluminum | from | from | from 0.01 | SiO₂: |
| | oxide, zirconium | non-heating to | 1.0 × 10⁻² | to 2.00 | A range from |
| | oxide, silicon | 350° C. | (Pa) to | nm/sec | 0.5 kw |
| | oxide, aluminum, | | 1.0 × 10² | | to 10 kw |
| | zirconium, and | | (Pa) | | |
| | silicon | | | | |
| H | Material including | | | | In the case of |
| | any of aluminum | | | | Nb₂O₅: |
| | oxide, zirconium | | | | A range from |
| | oxide, titanium | | | | 0.5 kw |
| | oxide, niobium | | | | to 5 kw |
| | oxide, tantalum | | | | |
| | oxide, aluminum, | | | | |
| | zirconium, | | | | |
| | titanium, niobium, | | | | |
| | and tantalum | | | | |
| L | Material including | | | | |
| | any of silicon oxide | | | | |
| | and silicon | | | | |

In Table 1 above, the following points are to be aware of.
Refractive index notation (λ = 550 nm)
M = 1.55 to 1.80
H = 1.80 to 2.60
L = 1.30 to 1.55

Below, Examples 1 to 6 made by inventors of the present invention and such to confirm effects of the optical thin film forming method in accordance with one embodiment of the present invention and part of Comparative examples are described. The Comparative example 1 is a case where an antireflection coating is formed by an evaporation method. The Comparative example 2 is a case where an antireflection coating is formed by a sputtering method.

Lens shapes, glass type names of substrates, the number of layers of antireflection coatings in Examples 1 to 6 and Comparative examples 1 and 2 are as follows. A glass type “B270” is made by SCHOTT AG and the other glass types are made by HOYA CORPORATION.

<List>

<<List of Examples>>

[Example 1] a concave hemispherical lens, B270, 7 layers

[Example 2] a concave hemispherical lens, B270, 7 layers

[Example 3] a concave aspherical lens, M-TAF101, 7 layers

[Example 4] a concave aspherical lens, M-TAFD305, 7 layers

[Example 5] a concave aspherical lens, M-TAFD305, 7 layers

[Example 6] a concave aspherical lens, M-TAFD305, a single layer (SiO₂)

<<List of Comparative Examples>>

[Comparative example 1] a concave aspherical lens, M-TAFD305, a single layer (SiO₂)

[Comparative example 2] a concave aspherical lens, M-TAFD305, a single layer (SiO₂)

In Table 2, film constitution materials, target materials, or evaporation materials, and applied refractive index used in Examples 1 to 6 and Comparative examples 1 and 2 are shown.

TABLE 2

| Refractive | Optical thin film | | |
|---|---|---|---|
| index | constituent | | Refractive |
| notation | material | Target material | index |
| M | Material including | Material including any of | 1.55 to |
| | any of aluminum | aluminum oxide, | 1.80 |
| | oxide, zirconium | zirconium oxide, silicon | |
| | oxide, and silicon | oxide, aluminum, | |
| | oxide | zirconium, and silicon | |
| H | Material including | Material including any of | 1.80 to |
| | any of aluminum | aluminum oxide, zirconium | 2.60 |
| | oxide, zirconium | oxide, titanium oxide, | |
| | oxide, titanium | niobium oxide, tantalum | |
| | oxide, niobium | oxide, aluminum, | |
| | oxide, and | zirconium, titanium, | |
| | tantalum oxide | niobium, and tantalum | |
| L | Material including | Material including any of | 1.30 to |
| | silicon oxide | silicon oxide and silicon | 1.55 |

In Table 2 above, the following points are to be aware of. Refractive indexes are refractive indexes at λ=550 nm.

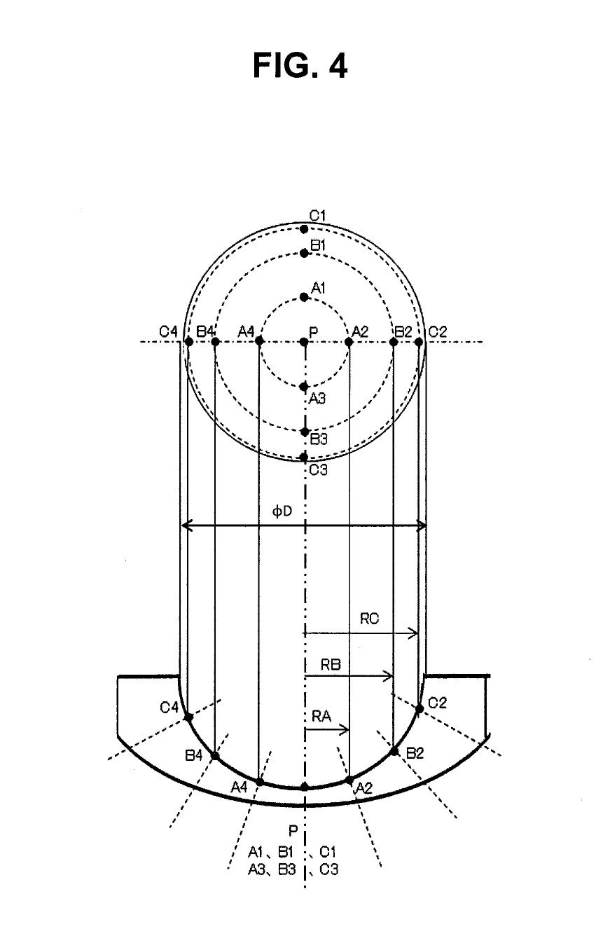

FIG. 4 is a view illustrating measurement areas of reflectance at a lens surface. FIG. 4 illustrates a top view and a cross section of a concave surface lens that is a target at which reflectance is measured in Examples 1 to 6 and Comparative examples 1 and 2

In Examples 1 to 6 and Comparative examples 1 and 2, measurement positions of reflectance are the center P, or the lens center position, on the optical axis 3A of the lens surface 3a of the optical lens 3, and a plurality of positions A1 to A4, B1 to B4, and C1 to C4, that are separated from the center P. Specifically, the measurement positions of reflectance A1 to A4 are arranged on the same circumference of a radius RA centered on the optical axis 3A in equal intervals. The measurement positions of reflectance B1 to B4 are arranged on the same circumference of a radius RB centered on the optical axis 3A in equal intervals. The measurement positions of reflectance C1 to C4 are arranged on the same circumference of a radius RC centered on the optical axis 3A in equal intervals. The measurement positions of reflectance Ai to Ci (i=1, 2, 3, 4) are arranged on the same radii.

More specifically, the center P on the optical axis 3A of the lens surface 3a, the plurality of positions A1 to A4 on the same circumference of the radius RA centered on the optical axis 3A of the lens surface 3a having a first surface angle at the lens surface 3a, for instance, of 30°, the plurality of positions B1 to B4 on the same circumference of the radius RB centered on the optical axis 3A of the lens surface 3a having a second surface angle larger than the first surface angle, for instance, of 40°, and the plurality of positions C1 to C4 on the same circumference of the radius RC centered on the optical axis 3A of the lens surface 3a having a third surface angle larger than the second surface angle, for instance, of 50°, are made to be positions of reflectance measurements. Each of measurement positions on a same circumference are positions having a 90° angle interval in the circumferential direction. As illustrated in a top view of an optical lens in FIG. 4, positions A1, B1, and C1, positions A2, B2, and C2, positions A3, B3, and C3, and positions A4, B4, and C4 are positioned on the same radii, respectively.

### Example 1

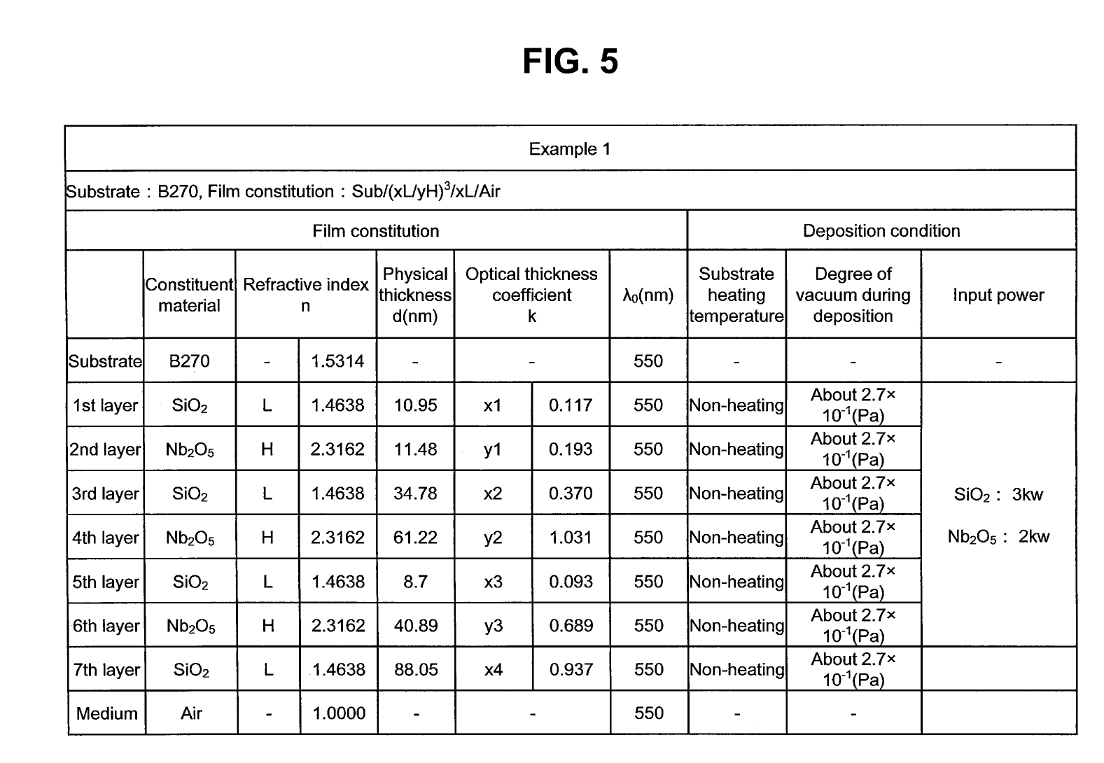

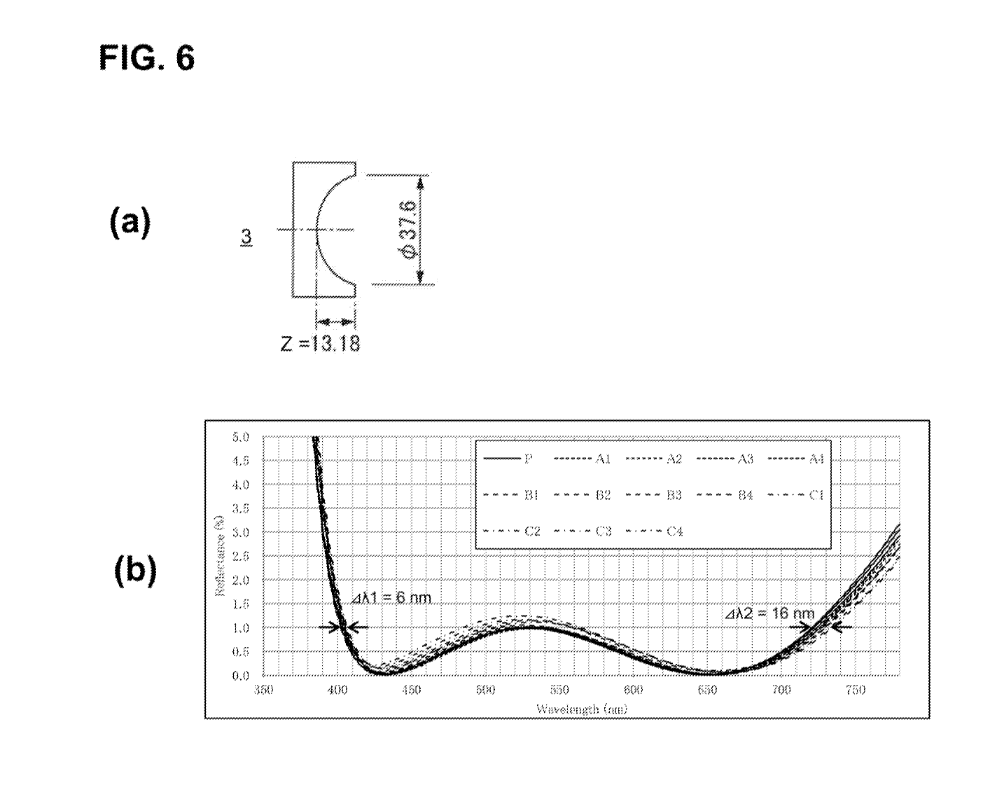

With the conditions such as film constitutions and film forming conditions shown in FIG. 5, an antireflection coating composed of 7 layers is formed on a concave hemispherical lens surface having a surface diameter φD of 37.6 mm, and a spherical segment length Z of 13.18 mm of a concave hemispherical lens of a shape illustrated in FIG. 6(a), where a radius of curvature R of the lens illustrated in FIG. 6(a) is 20 mm. Spectral reflectance of the formed antireflection coating is measured at each of the measurement positions illustrated in FIG. 4. The measurement positions are the lens center position P, and the positions in 4 directions having an angle interval of 90° in the circumferential direction centered on the lens optical axis. Each of the measurement positions in the circumferential direction is a measurement position at three positions having surface angles of 30°, 40°, and 50° in the radial direction. In the present example, the position having the surface angle of 30° is a position having a diameter of 15.2 mm centered on the optical axis, the position having the surface angle of 40° is a position having a diameter of 22.2 mm centered on the optical axis, and the position having the surface angle of 50° is a position having a diameter of 31.4 mm centered on the optical axis. Where “spectral reflectance” is reflectance represented as a function of wavelength (NPL: “an optical glossary P237, publisher: Ohm-Sha). In the Description, terms such as “spectral reflectance characteristics” and “characteristic curve” are used as the same meaning as “spectral reflectance”.

In the Description, x and y are used as symbols corresponding to an optical thickness coefficient k at a reference wavelength λ₀ of 550 nm. Specifically, the optical thickness coefficient k is represented by using x1 to x4 and y1 to y3. For numerical values of the optical thickness coefficients x and y, which shows a film constitution, the following numerical ranges may be applicable. An optical thickness is represented by a product of refractive index n and a physical thickness d, specifically, represented as nd=k×λ₀/4. These are the same for antireflection coatings of multilayer, or 7 layers, in Example 2 to 5.

x1=0.01 to 0.50

x2=0.01 to 0.60

x3=0.01 to 0.50

x4=0.70 to 1.30

y1=0.30 to 1.00

y2=0.80 to 1.50

y3=0.40 to 1.00

Here, during deposition by reactive sputtering, the maximum distance L (refer to FIG. 1) between the surface of the target 5 and the concave hemispherical lens surface of the concave hemispherical lens is configured at a value within a range of 30 mm to 50 mm. A deposition rate of each of the layers is controlled to be within a range of 0.01 to 2.00 nm/sec.

In FIG. 6(b), spectral reflectance characteristics of the formed 7 layer antireflection coating at each of the measurement positions are shown. Each curve, or a characteristic curve, representing spectral reflectance characteristics is a collection of measured values of spectral reflectance characteristics when a ray is incident at the concave hemispherical lens surface, which is an optical surface on which the antireflection coating is formed, at an incident angle of 0° by taking light reflectance (%) for a vertical axis and taking wavelength (nm) for a horizontal axis. Hereinafter, the same thing applies to spectral reflectance characteristics corresponding to the following Example 2 to 6 and Comparative example 1 and 2.

As it is understood from characteristic curves shown in FIG. 6(b), these curves have distributions in characteristics in each wavelength band of visible light. However, with an optical characteristic distribution of an extent to which the formed antireflection coating 14 generates between the center part and the peripheral part of the lens surface, when used as a lens, no ghost is generated in a photographed image and it may be said that the antireflection coating 14 of a substantially equal optical thickness is formed.

Here, ΔX, Δλ1, and Δλ2 are used as indexes for evaluating optical characteristics of the antireflection coating 14. Here, Δλ represents, when reflectance becomes no (n is an arbitrary value) a wavelength difference between a wavelength at the center P and a wavelength which is farthest from the wavelength at the center P among wavelengths at measurement positions other than the center P. Also, Δλ1 represents Δλ at a shortest wavelength side, and Δλ2 represents Δλ at a longest wavelength side. As the value of Δλ becomes small, a variation in reflectance at the measurement positions other than the center P and reflectance at the center P becomes small, which means, in other words, that a degree of uniformity of the optical thickness between the center P and at the measurement positions other than the center P is high, or an extent of a distribution is small. By using the Δλ, it is possible to determine whether or not an optical thickness at the center P and optical thicknesses at the measurement positions other than the center P are substantially equal.

The inventors calculate reference values of wavelength differences Δλ1 and Δλ2 on the basis of measurement results of optical characteristics, or spectral reflectance, by forming the antireflection coating 14 described in Examples 1 to 6. In Examples 1 to 6, when the wavelength difference is equal to the reference value or less, it is confirmed that no ghost is generated when a lens on which the antireflection coating 14 is formed by the present invention is used.

In Examples 1 to 6 and Comparative example 1 and 2, when Δλ1 is 30 nm or less assuming that reflectance is 1.0%, for instance, and/or when Δλ2 is 60 nm or less, it may be recognized that no variation in reflectance at the measurement positions other than the center P against reflectance at the center P exists, which means, in other words, that an optical thickness at each of the measurement positions is substantially equal, or uniform. Reference values used for determining whether or not an optical thickness is substantially equal, or uniform are not limited to what are described above, and may be changed according to performance and such required for the optical lens 3.

As it is understood from the characteristic curves shown in FIG. 6(b), concerning the antireflection coating formed in Example 1, Δλ1 for reflectance of 1.0% is 6 nm, shorter than 30 nm, which means that an antireflection coating of a substantially equal optical thickness is formed, and Δλ2 for reflectance of 1.0% is 16 nm, shorter than 60 nm, which means that an antireflection coating of a substantially equal optical thickness is formed.

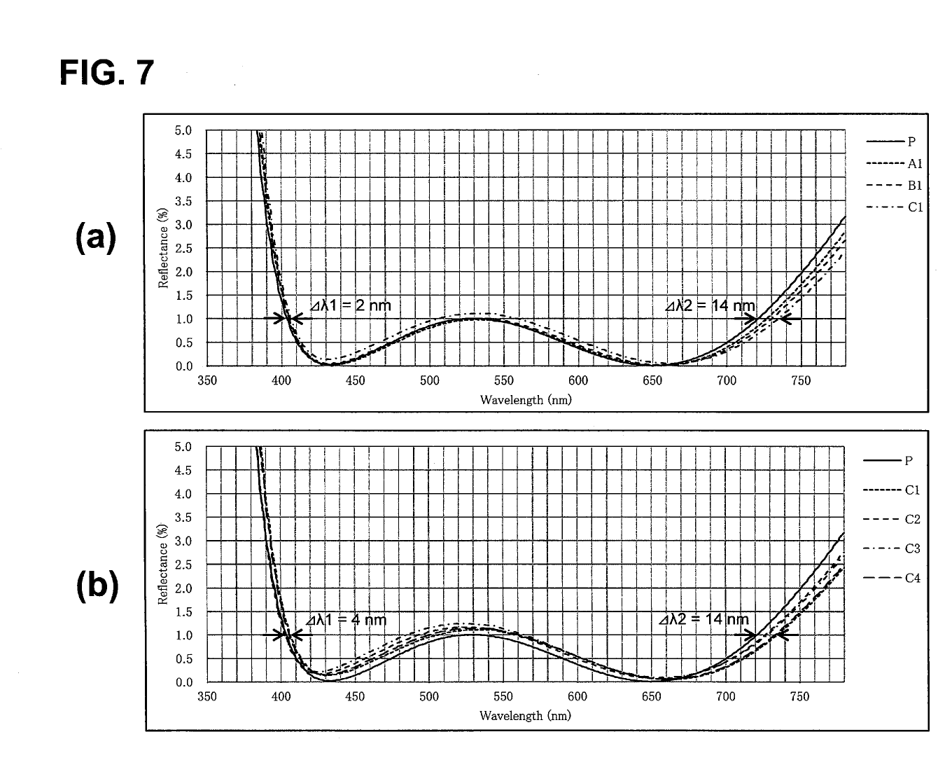

FIG. 7 is diagrams showing spectral reflectance characteristics of the antireflection coating at part of the measurement positions on the lens surface of the optical lens that is a target to be deposited in Example 1. FIG. 7(a) is a diagram showing spectral reflectance characteristics at the center P and a plurality of measurement positions A1, B1, and C1 arranged in a radial direction and FIG. 7(b) is a diagram showing spectral reflectance characteristics at the center P and a plurality of measurement positions C1, C2, C3, and C4 arranged in a circumferential direction.

As shown in FIG. 7(a), concerning the antireflection coating formed in Example 1, Δλ1 for reflectance of 1.0% at the plurality of measurement positions A1, B1, and C1 arranged in the radial direction is 2 nm, shorter than 30 nm, and Δλ2 is 14 nm, shorter than 60 nm, which means that a variation in an optical thickness of the antireflection coating between the center P and the plurality of measurement positions arranged in the radial direction is small.

As shown in FIG. 7(b), concerning the antireflection coating formed in Example 1, Δλ1 for reflectance of 1.0% at the plurality of measurement positions C1, C2, C3, and C4 arranged in the circumferential direction is 4 nm, not more than 30 nm, and Δλ2 is 14 nm, not more than 60 nm, which means that a variation in an optical thickness of the antireflection coating between the center P and the plurality of measurement positions arranged in the circumferential direction is small.

### Example 2

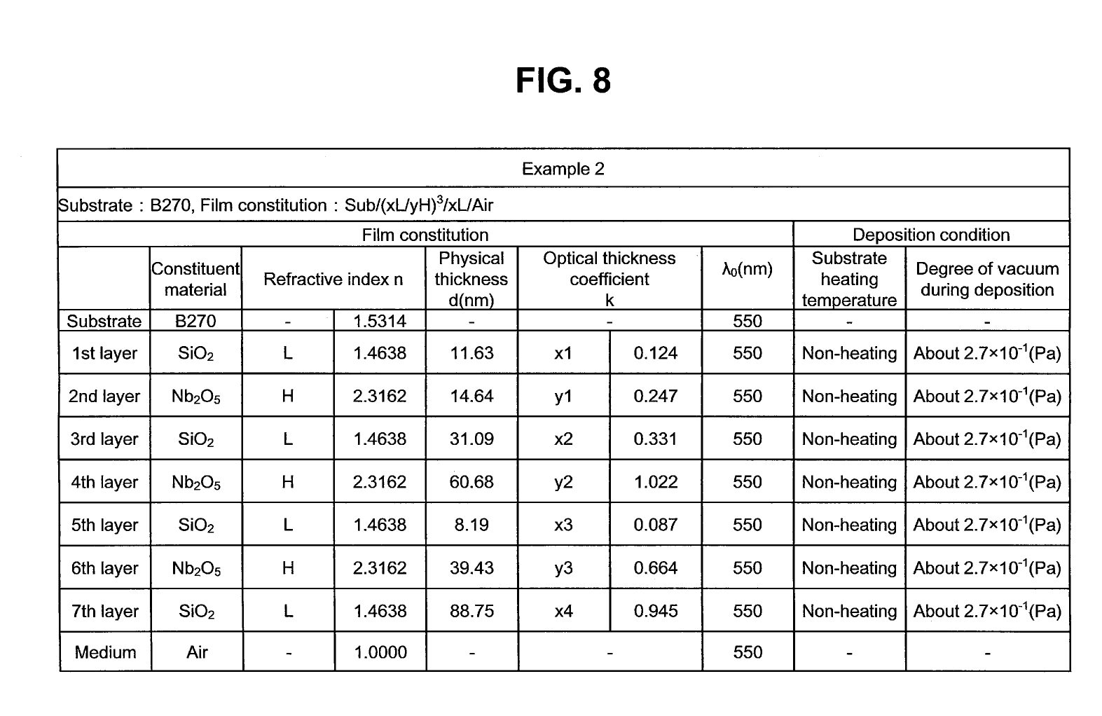

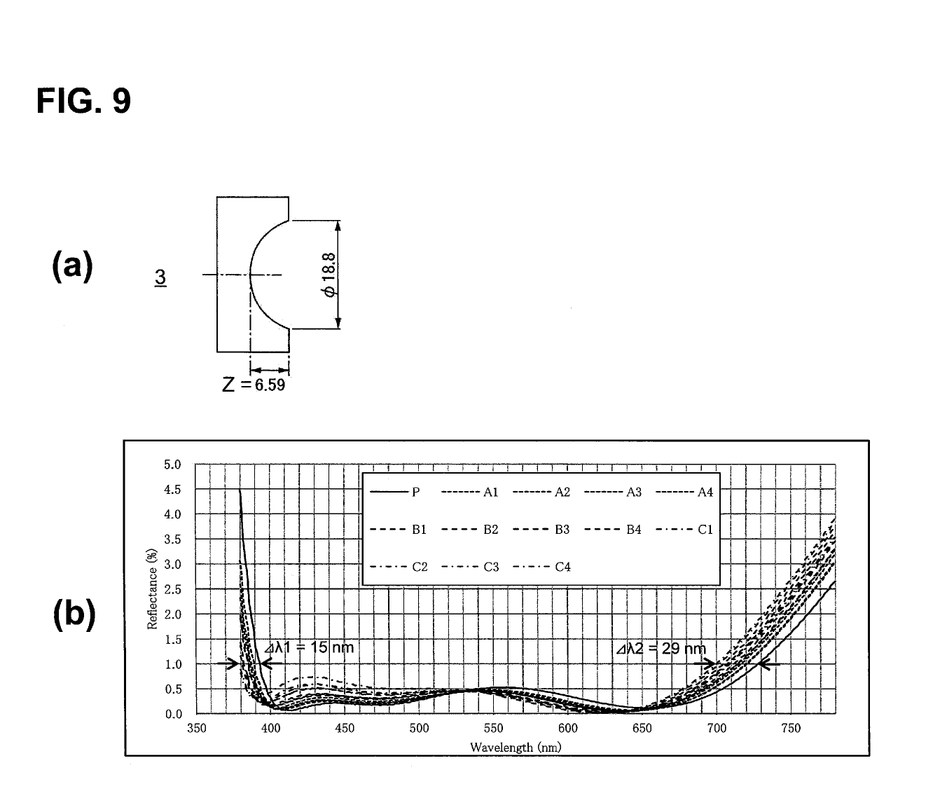

With the conditions such as film constitutions and film forming conditions shown in FIG. 8, an antireflection coating composed of 7 layers is formed on a concave hemispherical lens surface having a surface diameter φD of 18.8 m, and a spherical segment length Z of 6.59 mm of a concave hemispherical lens of a shape illustrated in FIG. 9(a), where a radius of curvature R of the lens illustrated in FIG. 9(a) is 10 mm. A concave hemispherical lens used in Example 2 has a surface diameter smaller than that of the concave hemispherical lens (refer to FIG. 6(a)) used in Example 1. Spectral reflectance of the formed antireflection coating is measured at each of the measurement positions similar to Example 1 (refer to FIG. 4). In this example, measurement positions having a surface angles of 30° are positions having a diameter of 7.6 mm, measurement positions having a surface angle of 40° are positions having a diameter of 11.1 mm, and measurement positions having a surface angle of 50° are positions having a diameter of 15.7 mm.

In this example also, during deposition by reactive sputtering, the maximum distance L (refer to FIG. 1) between the surface of the target and the concave hemispherical lens surface of the concave hemispherical lens is configured at a value within a range of 30 mm to 50 mm. Input power during deposition is configured at 3 kw for the case of SiO₂ film, and at 2 kw for the case of Nb₂O₅ film, and a deposition rate of each of the layers is controlled to be within a range of 0.01 to 2.00 nm/sec.

In FIG. 9(b), spectral reflectance characteristics of the formed 7 layer antireflection coating at each of the measurement positions are shown. These characteristic curves have distributions in characteristics in each wavelength band of visible light. However, with an optical characteristic distribution of an extent to which the formed antireflection coating 14 generates between the center part and the peripheral part of the lens surface, when used as a lens, no ghost is generated in a photographed image, which means that the antireflection coating of a substantially equal optical thickness is formed.

More specifically, As it is understood from characteristic curves shown in FIG. 9(b), concerning the antireflection coating formed in Example 2, Δλ1 for reflectance of 1.0% is 15 nm, shorter than 30 nm, which means that an antireflection coating of an extremely uniform, or a substantially equal, optical thickness is formed, and Δλ2 for reflectance of 1.0% is 29 nm, shorter than 60 nm, which means that an antireflection coating of a substantially equal optical thickness is formed.

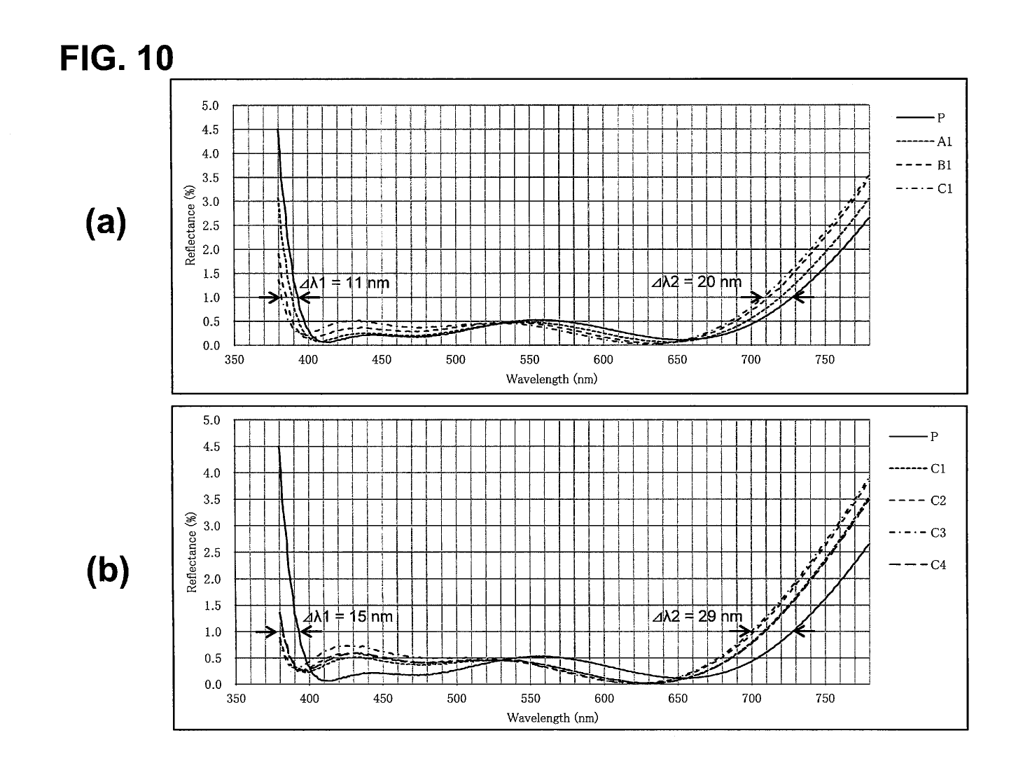

FIG. 10 is diagrams showing spectral reflectance characteristics of the antireflection coating at part of measurement positions on the lens surface of the optical lens that is a target to be deposited in Example 2. FIG. 10(a) is a diagram showing spectral reflectance characteristics at the center P and a plurality of measurement positions A1, B1, and C1 arranged in a radial direction and FIG. 10(b) is a diagram showing spectral reflectance characteristics at the center P and a plurality of measurement positions C1, C2, C3, and C4 arranged in a circumferential direction.

As shown in FIG. 10(a), concerning the antireflection coating formed in Example 2, Δλ1 for reflectance of 1.0% at the plurality of measurement positions A1, B1, and C1 arranged in the radial direction is 11 nm, shorter than 30 nm, and Δλ2 is 20 nm, shorter than 60 nm, which means that a variation in an optical thickness of the antireflection coating between the center P and the plurality of measurement positions arranged in the radial direction is small.

As shown in FIG. 10(b), concerning the antireflection coating formed in Example 2, Δλ1 for reflectance of 1.0% at the plurality of measurement positions C1, C2, C3, and C4 arranged in the circumferential direction is 15 nm, shorter than 30 nm, and Δλ2 is 29 nm, shorter than 60 nm, which means that a variation in an optical thickness of the antireflection coating between the center P and the plurality of measurement positions arranged in the circumferential direction is small.

### Example 3

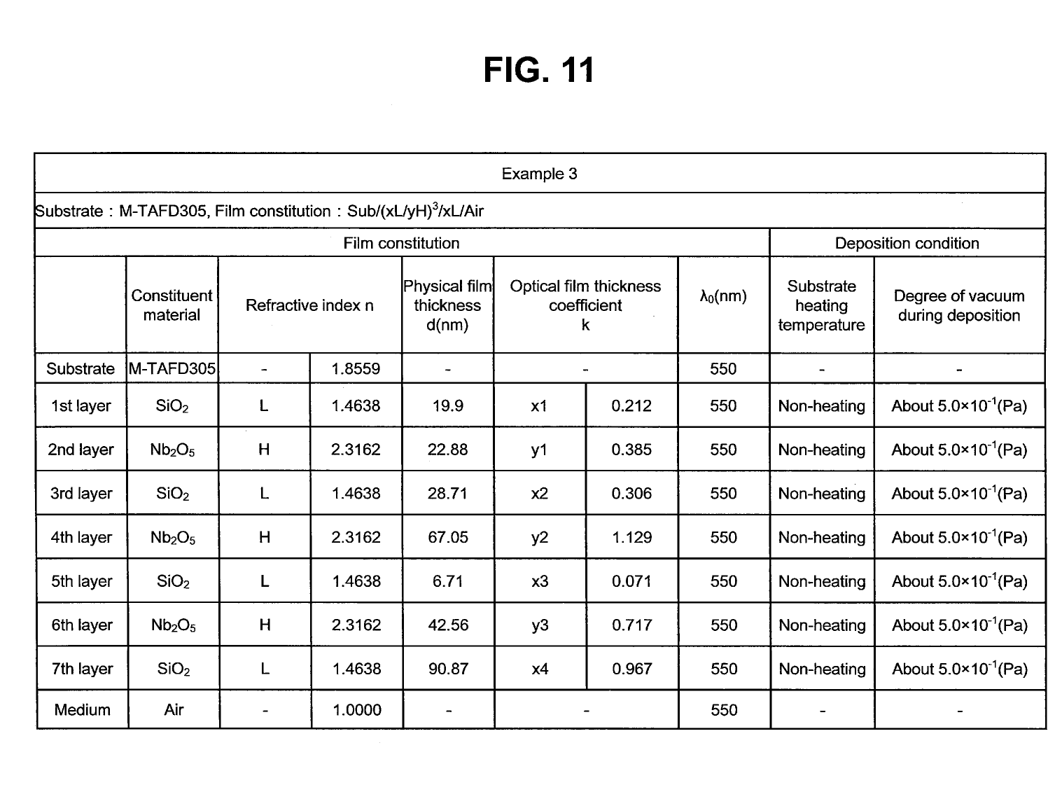

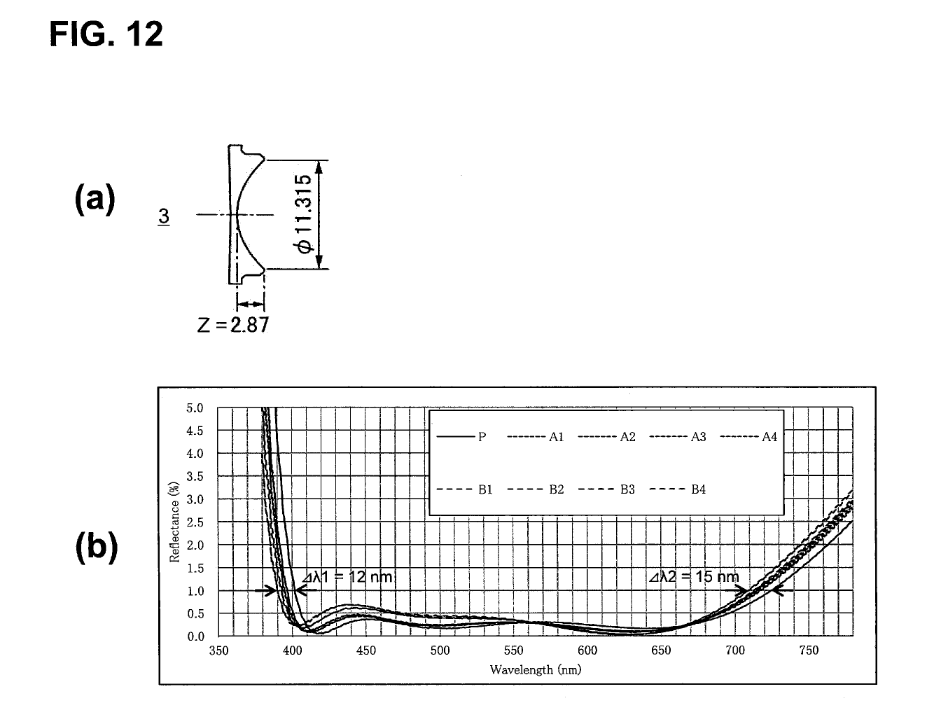

With the conditions such as film constitutions and film forming conditions shown in FIG. 11, an antireflection coating composed of 7 layers is formed on a concave aspherical lens surface having a surface diameter φD of 11.315 mm, a spherical segment length Z of 2.87 mm, concave R, or a radius of curvature at a paraxial curvature center, of 6.97 mm, and a maximum surface angle θ of 49.2°, of a concave aspherical lens of a shape illustrated in FIG. 12(a). A surface diameter of the concave hemispherical lens used in Example 3 is smaller than that of the concave hemispherical lens used in Example 2 (refer to FIG. 9(a)). Spectral reflectance of the formed antireflection coating is measured at center of the lens surface position and at four positions in each of the circumferential direction having 90° intervals around the optical axis, similar to the case of Example 1. At each of the measurement positions in the circumferential direction, measurements are performed at two positions, that are a measurement position having a surface angle of 28° and a diameter of 6.3 mm centered on the optical axis and a measurement position having a surface angle of 42° and a diameter of 9.5 mm centered on the optical axis. Here, each of the measurement positions of a surface angle of 28° is A1 to A4, each of the measurement positions of a surface angle of 42° is B1 to B4, and each of positions A1 and B1, positions A2 and B2, positions A3 and B3, and positions A4 and B4 are positions on a same radial line.

In this example also, during deposition by reactive sputtering, the maximum distance L (refer to FIG. 1) between the surface of the target and the concave aspherical lens surface of the concave aspherical lens is configured at a value within a range of 30 mm to 50 mm. Input power during deposition is configured at 3 kw for the case of SiO₂ film, and at 2 kw for the case of Nb₂O₅ film, and a deposition rate of each of the layers is controlled to be within a range of 0.01 to 2.00 nm/sec.

In FIG. 12(b), spectral reflectance characteristics of the formed 7 layer antireflection coating at each of the measurement positions are shown. These characteristic curves have distributions in characteristics in each wavelength band of visible light. However, with an optical characteristic distribution of an extent to which the formed antireflection coating generates between the center part and the peripheral part of the lens surface, when used as a lens, no ghost is generated in a photographed image, which means that the antireflection coating of a substantially equal optical thickness is formed.

More specifically, as it is understood from characteristic curves shown in FIG. 12(b), concerning the antireflection coating formed in Example 3, Δλ1 for reflectance of 1.0% is 12 nm, shorter than 30 nm, which means that an antireflection coating of a substantially equal optical thickness is formed, and Δλ2 for reflectance of 1.0% is 15 nm, shorter than 60 nm, which means that an antireflection coating of a substantially equal optical thickness is formed.

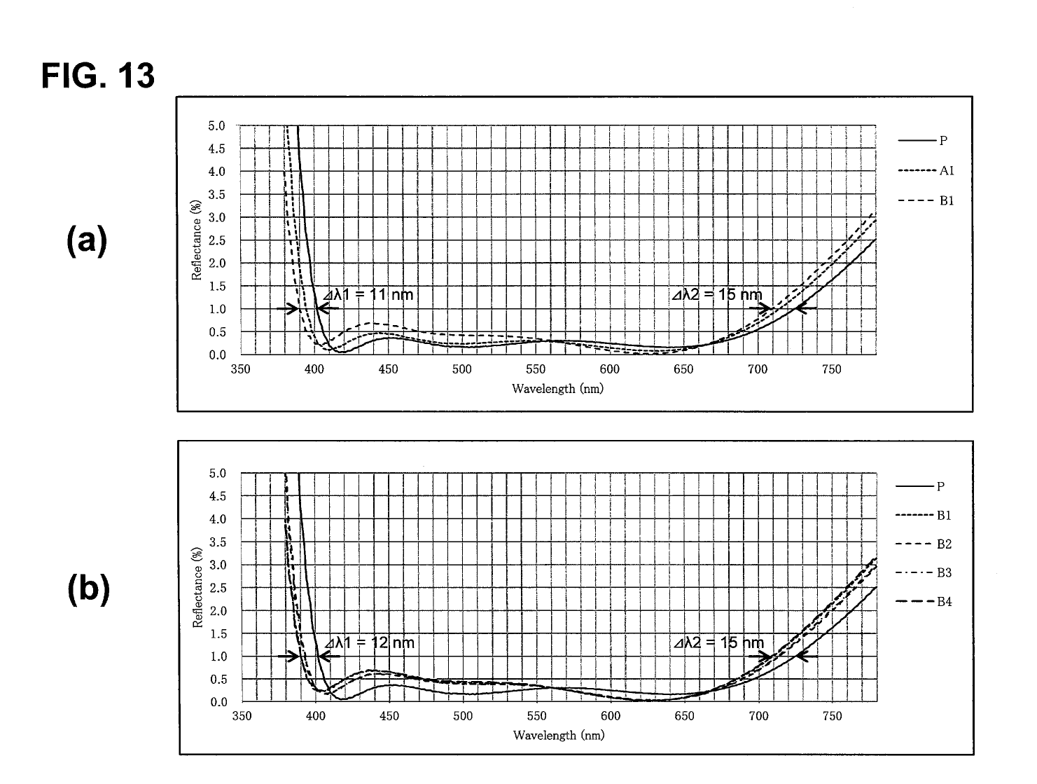

FIG. 13 is diagrams showing spectral reflectance characteristics of the antireflection coating at part of measurement positions on the lens surface of the optical lens that is a target to be deposited in Example 3. FIG. 13(a) is a diagram showing spectral reflectance characteristics at the center P and a plurality of measurement positions A1 and B1 arranged in a radial direction and FIG. 13(b) is a diagram showing spectral reflectance characteristics at the center P and a plurality of measurement positions B1, B2, B3, and B4 arranged in a circumferential direction.

As shown in FIG. 13(a), concerning the antireflection coating formed in Example 3, Δλ1 for reflectance of 1.0% at the plurality of measurement positions A1 and B1 arranged in the radial direction is 11 nm, shorter than 30 nm, and Δλ2 is 15 nm, shorter than 60 nm, which means that a variation in an optical thickness of the antireflection coating between the center P and the plurality of measurement positions arranged in the radial direction is small.

As shown in FIG. 13(b), concerning the antireflection coating formed in Example 3, Δλ1 for reflectance of 1.0% at the plurality of measurement positions B1, B2, B3, and B4 arranged in the circumferential direction is 12 nm, shorter than 30 nm, and Δλ2 is 15 nm, shorter than 60 nm, which means that a variation in an optical thickness of the antireflection coating between the center P and the plurality of measurement positions arranged in the circumferential direction is small.

### Example 4

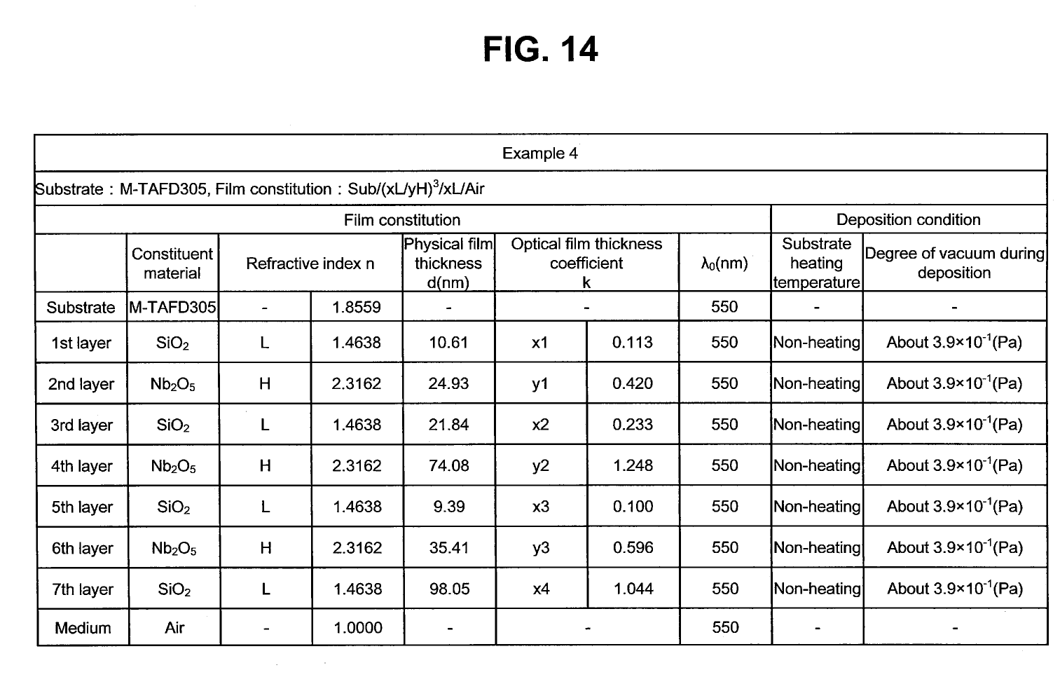

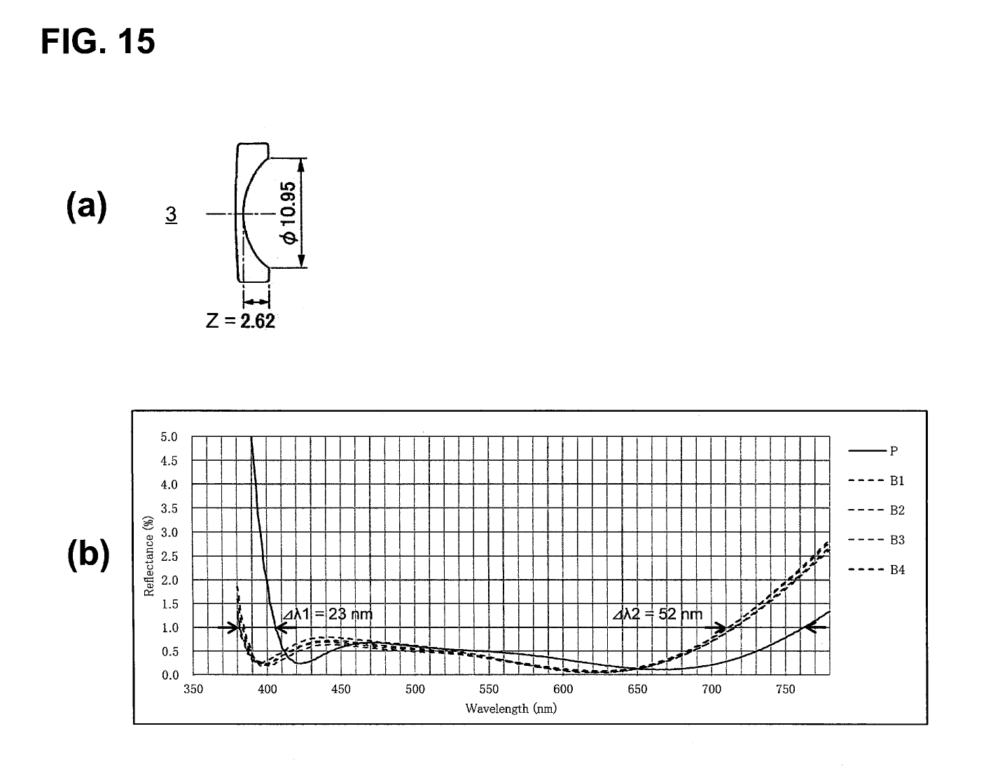

With the conditions such as film constitutions and film forming conditions shown in FIG. 14, an antireflection coating composed of 7 layers is formed on a concave aspherical lens surface having a surface diameter φD of 10.95 mm, a spherical segment length Z of 2.62 mm, concave R, or a radius of curvature at a paraxial curvature center, of 7.41 mm, and a maximum surface angle θ of 51.7°, of a concave aspherical lens of a shape illustrated in FIG. 15(a). Spectral reflectance of the formed antireflection coating is measured at center of the lens surface position P and at four positions in each of the circumferential direction having 90° intervals around the optical axis, similar to the case of Example 1. At each of the positions in the circumferential direction, a measurement is performed at a position, that is a measurement position having a surface angle of 40° and a diameter of 9.4 mm centered on the optical axis. Here, each of the measurement positions of a surface angle of 40° is B1 to B4.

In this example also, during deposition by reactive sputtering, the maximum distance L (refer to FIG. 1) between the surface of the target and the concave aspherical lens surface of the concave aspherical lens is configured at a value within a range of 100 mm to 200 mm. Input power during deposition is configured at 3 kw for the case of SiO₂ film, and at 2 kw for the case of Nb₂O₅ film, and a deposition rate of each of the layers is controlled to be within a range of 0.01 to 2.00 nm/sec.

In FIG. 15(b), spectral reflectance characteristics of the formed 7 layer antireflection coating at each of the measurement positions are shown. Spectral reflectance at the center of the lens surface position and peripheral positions at each wavelength band of visible light is suppressed to a variation of an extent practically causing no problem, or to an extent generating no ghost in a photographed image when used as a lens, it is confirmed that, as a whole, an antireflection coating having an optical thickness of substantially equal is formed.

More specifically, as it is understood from characteristic curves shown in FIG. 15(b), concerning the antireflection coating formed in Example 4, Δλ1 for reflectance of 1.0% is 23 nm, shorter than 30 nm, which means that an antireflection coating of a substantially equal optical thickness is formed, and Δλ2 for reflectance of 1.0% is 52 nm, shorter than 60 nm, which means that an antireflection coating of a substantially equal optical thickness is formed.

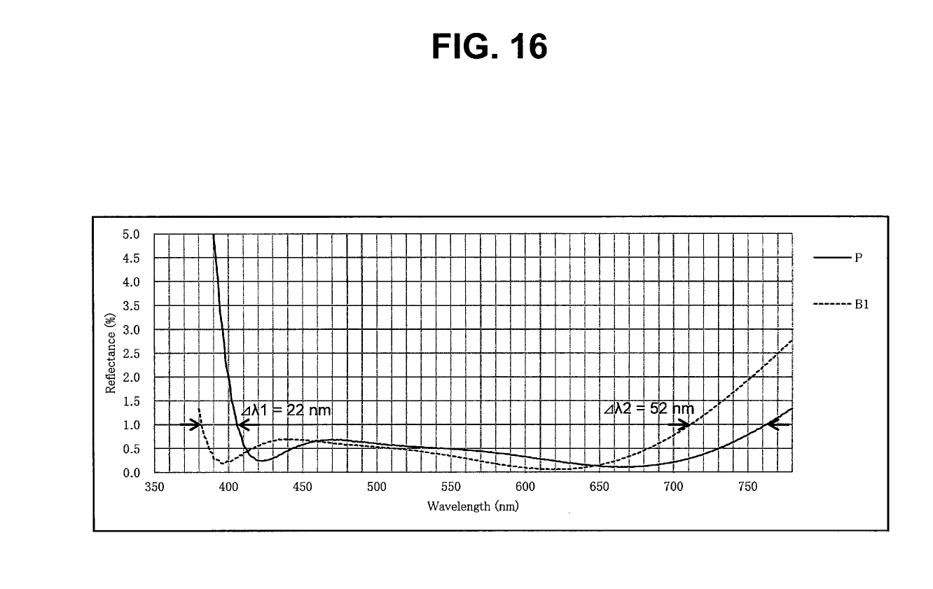

FIG. 16 is diagrams showing spectral reflectance characteristics of the antireflection coating at part of measurement positions on the lens surface of the optical lens that is a target to be deposited in Example 4. FIG. 16 is a diagram showing spectral reflectance characteristics at the center P and a measurement position B1 arranged in a radial direction.

As shown in FIG. 16, concerning the antireflection coating formed in Example 4, Δλ1 for reflectance of 1.0% at the measurement position B1 is 22 nm, shorter than 30 nm, and Δλ2 is 52 nm, shorter than 60 nm, which means that a variation in an optical thickness of the antireflection coating between the center P and the measurement position in the radial direction is small.

### Example 5

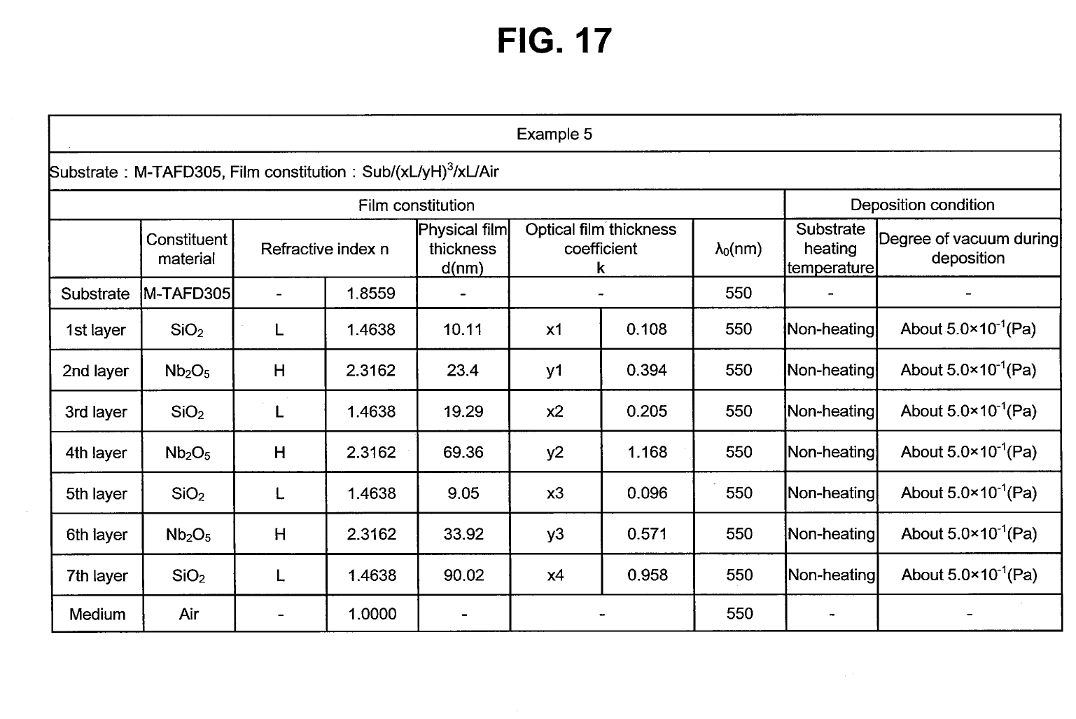

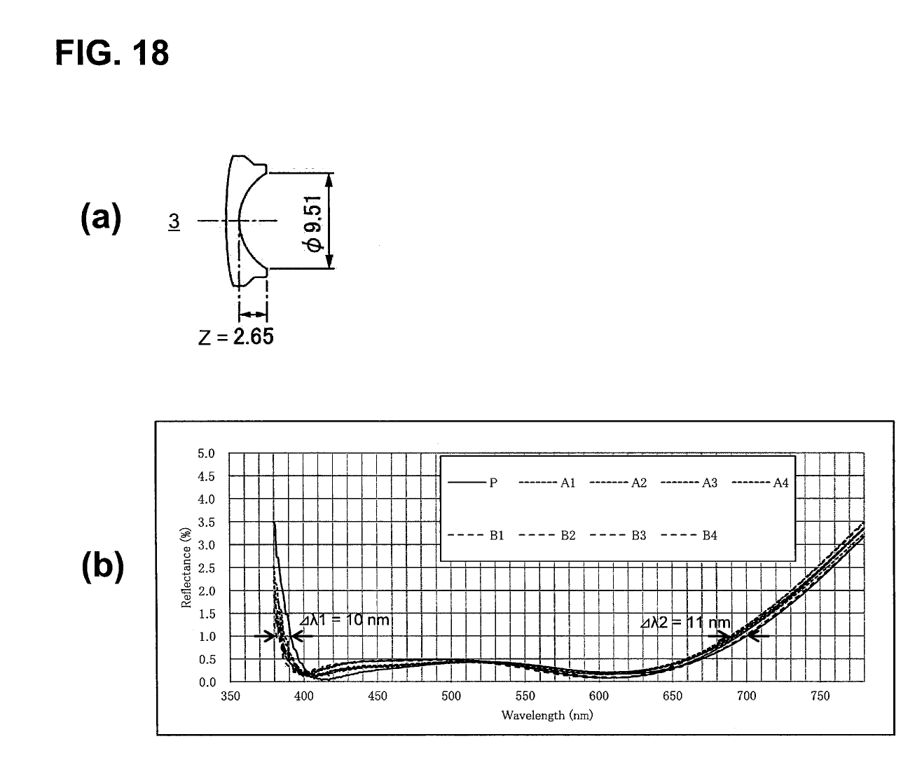

With the conditions such as film constitutions and film forming conditions shown in FIG. 17, an antireflection coating composed of 7 layers is formed on a concave aspherical lens surface having a surface diameter φD of 9.51 mm, a spherical segment length d of 2.65 mm, concave R, or a radius of curvature at a paraxial curvature center, of 4.90 mm, and a maximum surface angle θ of 49.4°, of a concave aspherical lens of a shape illustrated in FIG. 18(a). Spectral reflectance of the formed antireflection coating is measured at center of the lens surface position and at four positions in each of the circumferential direction having 90° intervals around the optical axis, similar to the case of Example 1. At each of the measurement positions in the circumferential direction, measurements are performed at two positions, that are a measurement position having a surface angle of 28° and a diameter of 5.0 mm centered on the optical axis and a measurement position having a surface angle of 42° and a diameter of 7.6 mm centered on the optical axis. Here, each of the measurement positions of a surface angle of 28° is A1 to A4, each of the measurement positions of a surface angle of 42° is B1 to B4, and each of positions A1 and B1, positions A2 and B2, positions A3 and B3, and positions A4 and B4 are positions on a same radial line.

In this example also, during deposition by reactive sputtering, the maximum distance L (refer to FIG. 1) between the surface of the target and the concave aspherical lens surface of the concave aspherical lens is configured at a value within a range of 30 mm to 50 mm. Input power during deposition is configured at 3 kw for the case of SiO₂ film, and at 2 kw for the case of Nb₂O₅ film, and a deposition rate of each of the layers is controlled to be within a range of 0.01 to 2.00 nm/sec.

In FIG. 18(b), spectral reflectance characteristics of the formed 7 layer antireflection coating at each of the measurement positions are shown. These characteristic curves have distributions in characteristics in each wavelength band of visible light. However, with an optical characteristic distribution of an extent to which the formed antireflection coating 14 generates between the center part and the peripheral part of the lens surface, when used as a lens, no ghost is generated in a photographed image, which means that the antireflection coating of a substantially equal optical thickness is formed.

More specifically, as it is understood from characteristic curves shown in FIG. 18(b), concerning the antireflection coating formed in Example 5, Δλ1 for reflectance of 1.0% is 10 nm, shorter than 30 nm, which means that an antireflection coating of a substantially equal optical thickness is formed, and Δλ2 for reflectance of 1.0% is 11 nm, shorter than 60 nm, which means that an antireflection coating of a substantially equal optical thickness is formed.

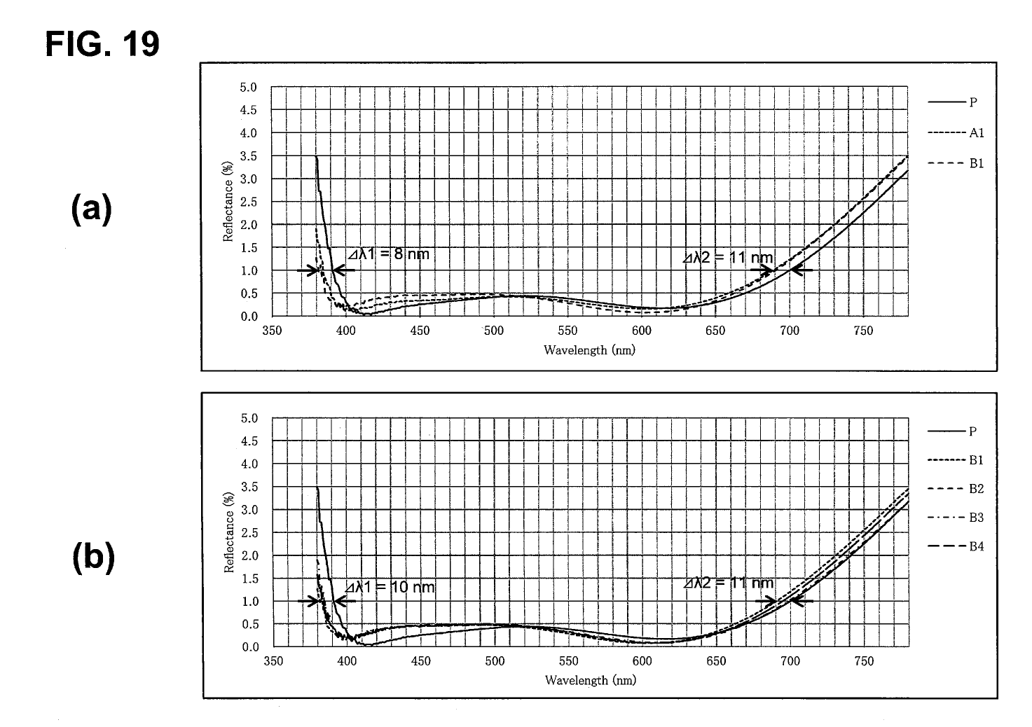

FIG. 19 is diagrams showing spectral reflectance characteristics of the antireflection coating at part of measurement positions on the lens surface of the optical lens that is a target to be deposited in Example 5. FIG. 19(a) is a diagram showing spectral reflectance characteristics at the center P and a plurality of measurement positions A1 and B1 arranged in a radial direction and FIG. 19(b) is a diagram showing spectral reflectance characteristics at the center P and a plurality of measurement positions B1, B2, B3, and B4 arranged in a circumferential direction.

As shown in FIG. 19(a), concerning the antireflection coating formed in Example 5, Δλ1 for reflectance of 1.0% at the plurality of measurement positions A1 and B1 arranged in the radial direction is 8 nm, shorter than 30 nm, and Δλ2 is 11 nm, shorter than 60 nm, which means that a variation in an optical thickness of the antireflection coating between the center P and the plurality of measurement positions arranged in the radial direction is small.

As shown in FIG. 19(b), concerning the antireflection coating formed in Example 5, Δλ1 for reflectance of 1.0% at the plurality of measurement positions B1, B2, B3, and B4 arranged in the circumferential direction is 10 nm, shorter than 30 nm, and Δλ2 is 11 nm, shorter than 60 nm, which means that a variation in an optical thickness of the antireflection coating between the center P and the plurality of measurement positions arranged in the circumferential direction is small.

### Example 6

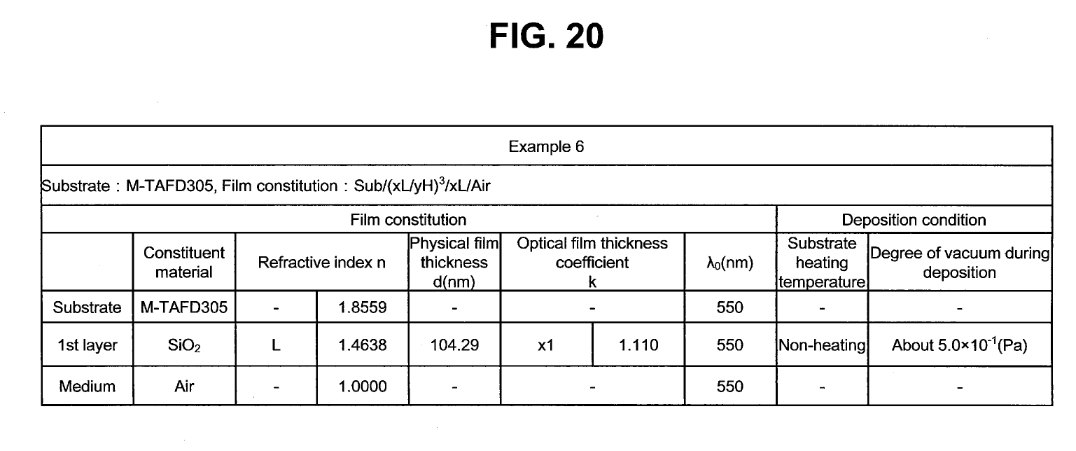

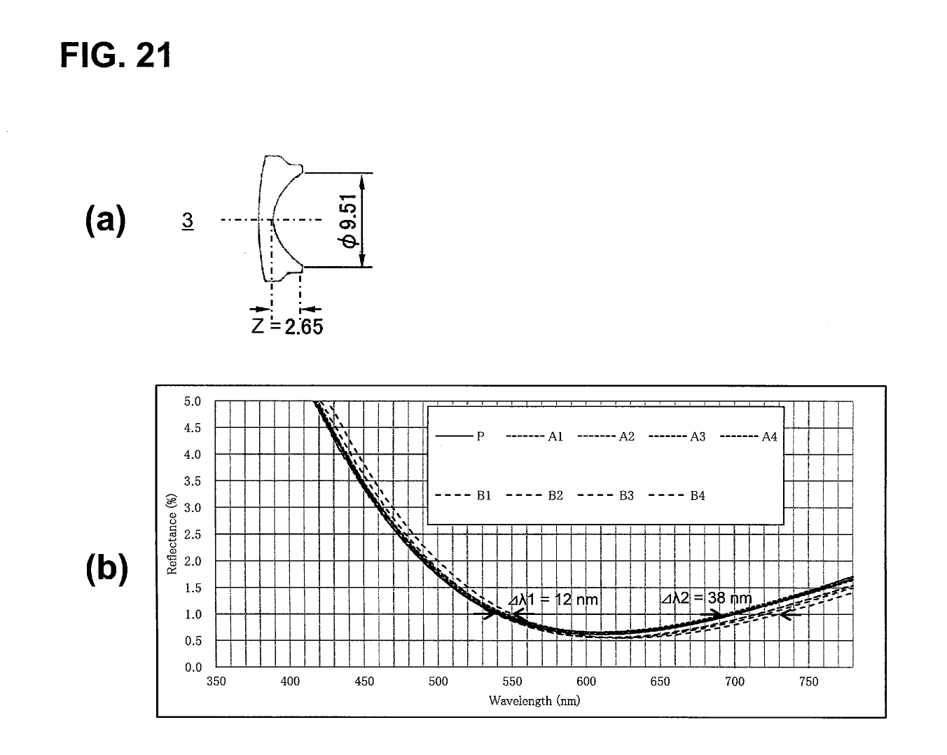

With the conditions such as film constitutions and film forming conditions shown in FIG. 20, an antireflection coating composed of a single layer is formed on a concave aspherical lens surface having a surface diameter φD of 9.51 mm, a spherical segment length Z of 2.65 mm, concave R, or a radius of curvature at a paraxial curvature center, of 4.90 mm, and a maximum surface angle θ of 49.4°, of a concave aspherical lens of a shape illustrated in FIG. 21(a). Spectral reflectance of the formed antireflection coating is measured at center of the lens surface position and at four positions in each of the circumferential direction having 90° intervals around the optical axis, similar to the case of Example 1. At each of the measurement positions in the circumferential direction, measurements are performed at two positions, that are a measurement position having a surface angle of 28° and a diameter of 5.0 mm centered on the optical axis and a measurement position having a surface angle of 42° and a diameter of 7.6 mm centered on the optical axis. Here, each of the measurement positions of a surface angle of 28° is A1 to A4, each of the measurement positions of a surface angle of 42° is B1 to B4, and each of positions A1 and B1, positions A2 and B2, positions A3 and B3, and positions A4 and B4 are positions on a same radial line.

Similar to Example 1 described above, x1 is used as a symbol corresponding to an optical thickness coefficient k at a reference wavelength λ₀ of 550 nm. For a numerical value of the optical thickness coefficient x, which shows a film constitution, the following numerical range may be applicable. An optical thickness is represented by a product of refractive index n and a physical thickness d, specifically, represented as nd=k×λ₀/4.

x1=0.70 to 1.30

In this example also, during deposition by reactive sputtering, the maximum distance L (refer to FIG. 1) between the surface of the target and the concave aspherical lens surface of the concave aspherical lens is configured at a value within a range of 30 mm to 50 mm. Input power during deposition is configured at 3 kw, and a deposition rate is controlled to be within a range of 0.01 to 2.00 nm/sec.

In FIG. 21(b), spectral reflectance characteristics of the formed single layer antireflection coating at each of the measurement positions are shown. These characteristic curves have distributions in characteristics in each wavelength band of visible light. However, with an optical characteristic distribution of an extent to which the formed antireflection coating generates between the center part and the peripheral part of the lens surface, when used as a lens, no ghost is generated in a photographed image, which means that an antireflection coating of a substantially equal optical thickness is formed.

More specifically, as it is understood from characteristic curves shown in FIG. 21(b), concerning the antireflection coating formed in Example 6, Δλ1 for reflectance of 1.0% is 12 nm, shorter than 30 nm, which means that an antireflection coating of a substantially equal optical thickness is formed, and Δλ2 for reflectance of 1.0% is 38 nm, shorter than 60 nm, which means that an antireflection coating of a substantially equal optical thickness is formed.

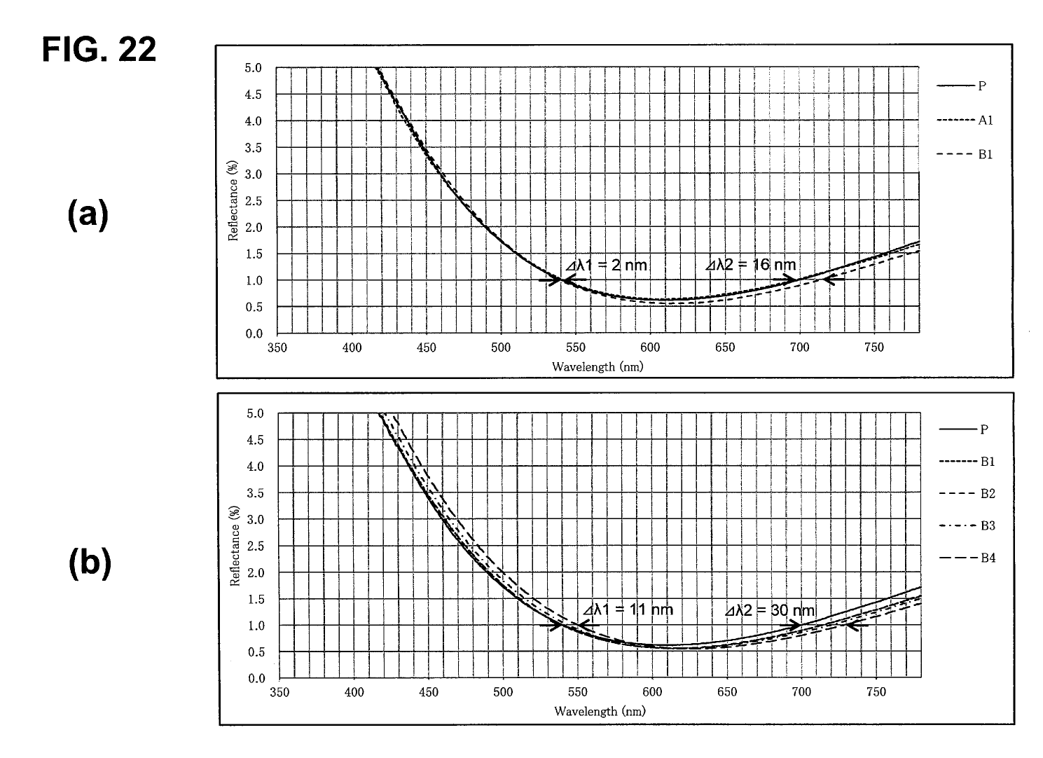

FIG. 22 is diagrams showing spectral reflectance characteristics of the antireflection coating at part of measurement positions on the lens surface of the optical lens that is a target to be deposited in Example 6. FIG. 22(a) is a diagram showing spectral reflectance characteristics at the center P and a plurality of measurement positions A1 and B1 arranged in a radial direction and FIG. 22(b) is a diagram showing spectral reflectance characteristics at the center P and a plurality of measurement positions B1, B2, B3, and B4 arranged in a circumferential direction.

As shown in FIG. 22(a), concerning the antireflection coating formed in Example 6, Δλ1 for reflectance of 1.0% at the plurality of measurement positions A1 and B1 arranged in the radial direction is 2 nm, shorter than 30 nm, and Δλ2 is 16 nm, shorter than 60 nm, which means that a variation in an optical thickness of the antireflection coating between the center P and the plurality of measurement positions arranged in the radial direction is small.

As shown in FIG. 22(b), concerning the antireflection coating formed in Example 6, Δλ1 for reflectance of 1.0% at the plurality of measurement positions B1, B2, B3, and B4 arranged in the circumferential direction is 11 nm, shorter than 30 nm, and Δλ2 is 30 nm, shorter than 60 nm, which means that a variation in an optical thickness of the antireflection coating between the center P and the plurality of measurement positions arranged in the circumferential direction is small.

### Comparative Example 1

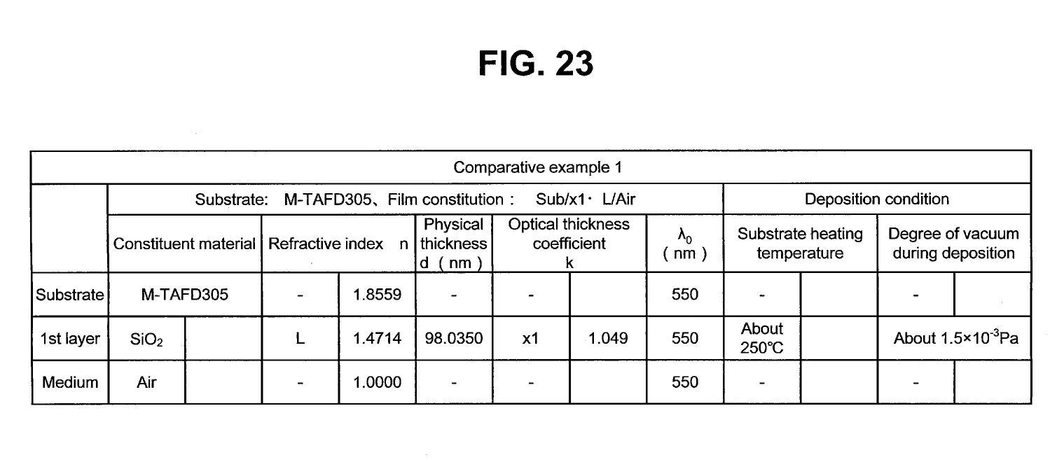

To compare with Examples 1 to 6 of one embodiment of the present invention, with the conditions such as film constitutions and film forming conditions shown in FIG. 23, an antireflection coating composed of a single layer is formed by an evaporation method on a concave aspherical lens surface having a surface diameter φD of 10.95 mm, a spherical segment length Z of 2.62 mm, concave R, or a radius of curvature at a paraxial curvature center, of 7.41 mm, and a maximum surface angle θ of 51.7°, of a concave aspherical lens (M-TAFD305, SiO₂ single layer). Spectral reflectance of the formed antireflection coating is measured at center of the lens surface position and at four positions in each of the circumferential direction having 90° intervals around the optical axis, similar to the case of Example 6. At each of the measurement positions in the circumferential direction, measurements are performed at two positions, that are a measurement position having a surface angle of 28° and a diameter of 6.8 mm centered on the optical axis and a measurement position having a surface angle of 42° and a diameter of 9.6 mm centered on the optical axis. Here, each of the measurement positions of a surface angle of 28° is A1 to A4, each of the measurement positions of a surface angle of 42° is B1 to B4, and each of positions A1 and B1, positions A2 and B2, positions A3 and B3, and positions A4 and B4 are positions on a same radial line.

For a numerical value of the optical thickness coefficient x1, which shows a film constitution, the following numerical range may be applicable. An optical thickness nd is represented similarly to the Examples described above.

x1=0.70 to 1.30

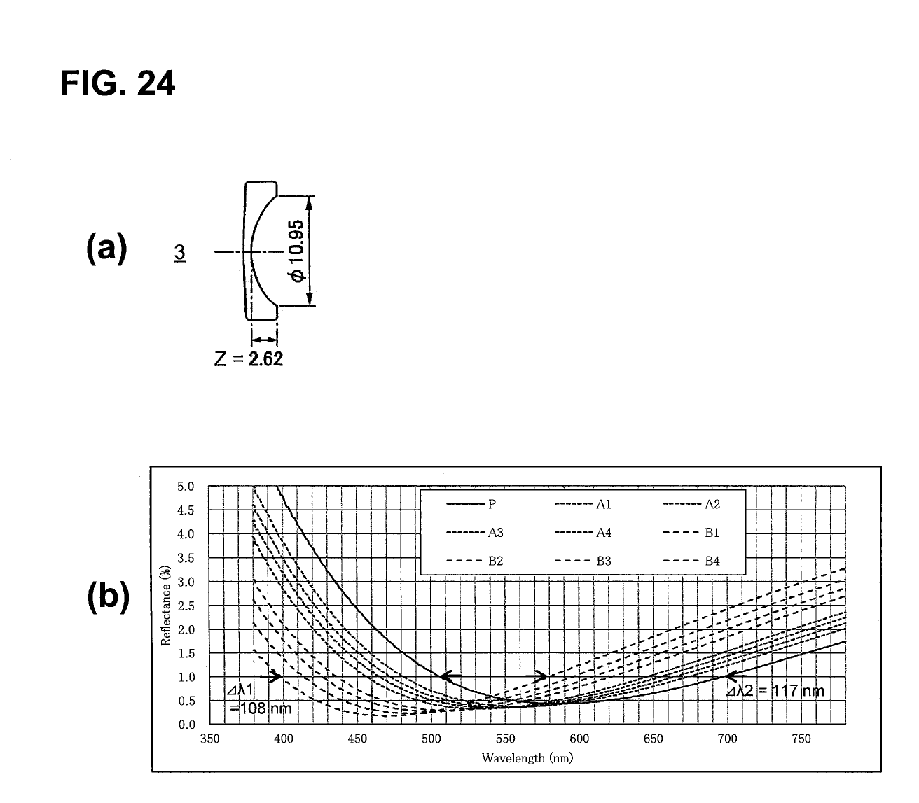

In FIG. 24(b), spectral reflectance characteristics of the formed antireflection coating at each of the measurement positions are shown. As it is understood from these characteristic curves, at the center of the lens surface, the peripheral part of the lens surface, and at a lens surface position therebetween, characteristics are mutually significantly deviated.

Comparative example 1 is a comparison with Example 6. Example 6 and Comparative example 1 are the same in terms of the constituent materials and the antireflection coatings being made from a single layer (SiO₂) and they are different in terms of film forming methods.

More specifically, as it is understood from characteristic curves shown in FIG. 24(b), concerning the antireflection coating formed in Comparative example 1, since Δλ1 for reflectance of 1.0% is 108 nm, larger than 30 nm, and Δλ2 for reflectance of 1.0% is 117 nm, larger than 60 nm, ghost is generated when used as a lens. In other words, it may be said that optical thicknesses are substantially different. In comparison to this, in Example 6 in which the antireflection coating is formed on the lens surface by the optical thin film forming method in accordance with one embodiment of the present invention, Δλ1 for reflectance of the antireflection coating of 1.0% is 12 nm, and Δλ2 for reflectance of 1.0% is 38 nm, which means that an antireflection coating of a substantially equal optical thickness is formed, and superiority of forming an antireflection coating by the optical thin film forming method in accordance with one embodiment of the present invention may be confirmed.

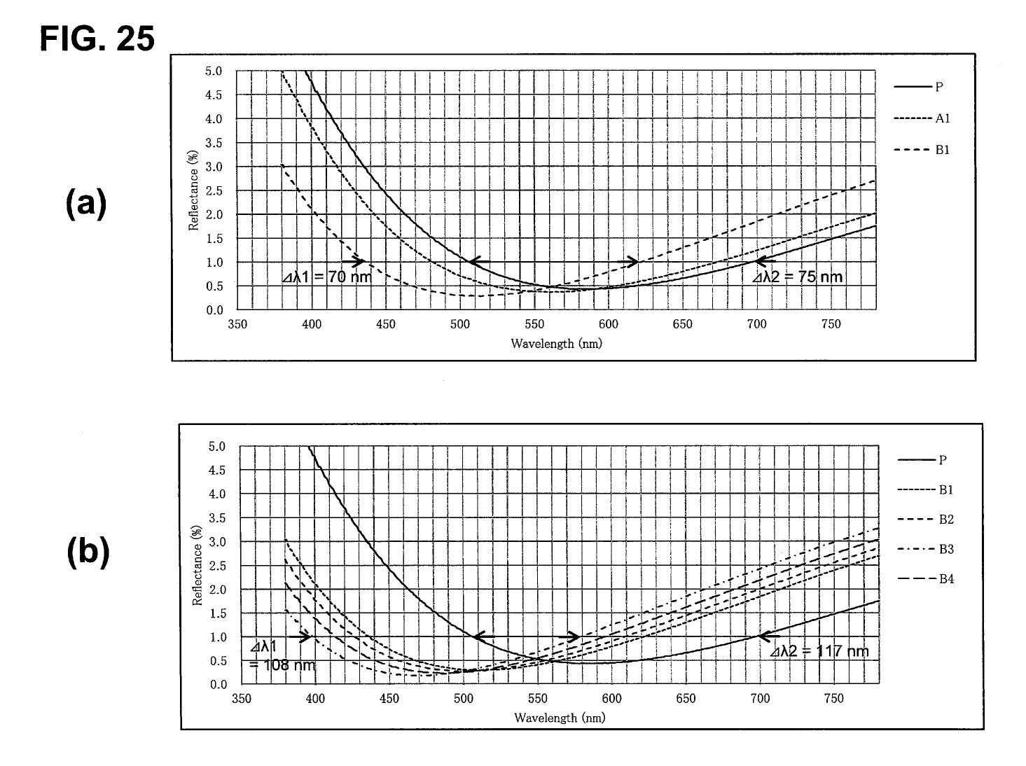

FIG. 25 is diagrams showing spectral reflectance characteristics of the antireflection coating at part of measurement positions on the lens surface of the optical lens that is a target to be deposited in Comparative example 1. FIG. 25(a) is a diagram showing spectral reflectance characteristics at the center P and a plurality of measurement positions A1 and B1 arranged in a radial direction and FIG. 25(b) is a diagram showing spectral reflectance characteristics at the center P and a plurality of measurement positions B1, B2, B3, and B4 arranged in a circumferential direction.

As shown in FIG. 25(a), concerning the antireflection coating formed in Comparative example 1, since Δλ1 for reflectance at the plurality of measurement positions A1 and B1 arranged in the radial direction of 1.0% is 70 nm, larger than 30 nm, and Δλ2 for reflectance of 1.0% is 75 nm, larger than 60 nm, which means that a variation in an optical thickness of the antireflection coating between the center P and the plurality of measurement position arranged in the radial direction is large. In comparison to this, in Example 6 in which the antireflection coating is formed on the lens surface by the optical thin film forming method in accordance with one embodiment of the present invention, Δλ1 for reflectance of the antireflection coating at the plurality of measurement positions arranged in the circumferential direction of 1.0% is 2 nm, and Δλ2 for reflectance of 1.0% is 16 nm, which means that an antireflection coating of a substantially equal optical thickness is formed, and superiority of forming an antireflection coating by the optical thin film forming method in accordance with one embodiment of the present invention may be confirmed.

As shown in FIG. 25(b), concerning the antireflection coating formed in Comparative example 1, Δλ1 for reflectance of 1.0% at the plurality of measurement positions B1, B2, B3, and B4 arranged in the circumferential direction is 108 nm, larger than 30 nm, and Δλ2 is 117 nm, larger than 60 nm, which means that a variation in an optical thickness of the antireflection coating between the center P and the plurality of measurement positions arranged in the circumferential direction is large. In comparison to this, in Example 6 in which the antireflection coating is formed on the lens surface by the optical thin film forming method in accordance with one embodiment of the present invention, Δλ1 for reflectance at a plurality of measurement positions arranged in the circumferential direction of the antireflection coating of 1.0% is 11 nm, and Δλ2 for reflectance of 1.0% is 30 nm, which means that an antireflection coating of a substantially equal optical thickness is formed, and superiority of forming an antireflection coating by the optical thin film forming method in accordance with one embodiment of the present invention may be confirmed.

As described above, as shown in FIG. 25(b) although it is not possible to form an antireflection coating of a substantially equal optical thickness by an evaporation method, it is possible to form an antireflection coating of a substantially equal optical thickness by the optical thin film forming method in accordance with one embodiment of the present invention.

### Comparative Example 2

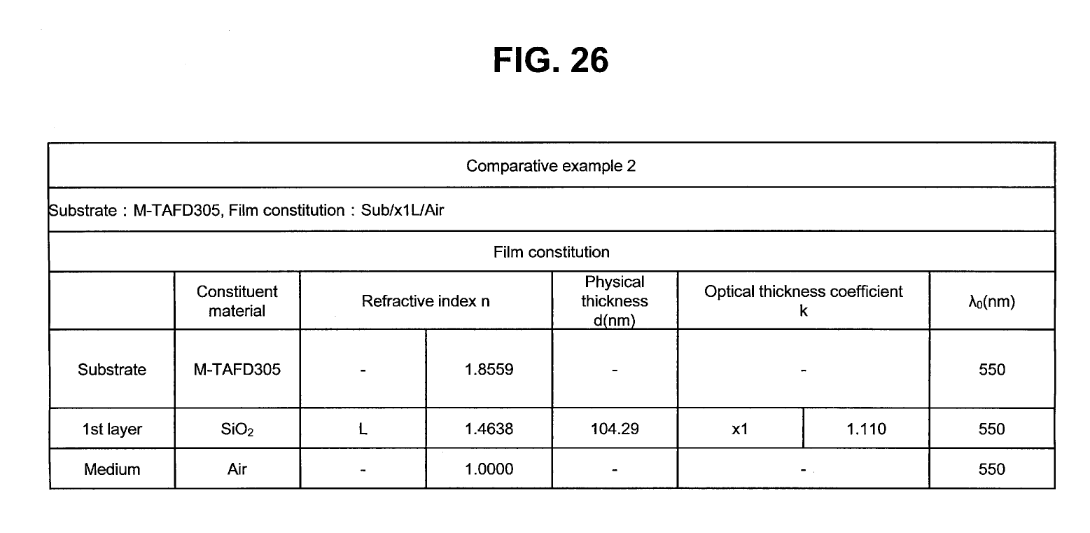

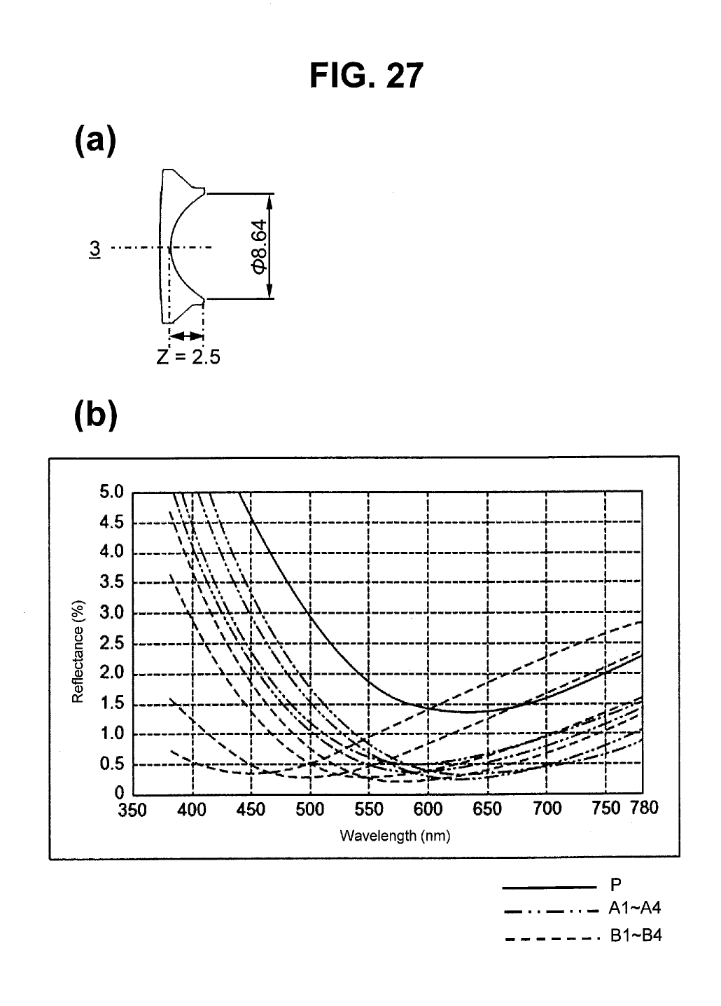

With the conditions such as film constitutions and film forming conditions shown in FIG. 26, an antireflection coating composed of a single layer is formed by a sputtering method on a concave aspherical lens surface having a surface diameter φD of 8.64 mm, a spherical segment length Z of 2.5 mm, concave R, or a radius of curvature at a paraxial curvature center, of 4.92 mm, and a maximum surface angle θ of 51.8°, of a concave aspherical lens (M-TAFD305, SiO₂ single layer) illustrated in FIG. 27(a). Spectral reflectance of the formed antireflection coating is measured at center of the lens surface position and at four positions in each of the circumferential direction having 90° intervals around the optical axis, similar to the case of Example 6. At each of the measurement positions in the circumferential direction, measurements are performed at two positions, that are a measurement position having a surface angle of 28° and a diameter of 4.5 mm centered on the optical axis and a measurement position having a surface angle of 42° and a diameter of 6.6 mm centered on the optical axis. Here, each of the measurement positions of a surface angle of 28° is A1 to A4, each of the measurement positions of a surface angle of 42° is B1 to B4, and each of positions A1 and B1, positions A2 and B2, positions A3 and B3, and positions A4 and B4 are positions on a same radial line.

For a numerical value of the optical thickness coefficient x1, which shows a film constitution, the following numerical range may be applicable. An optical thickness nd may be represented similarly to the Examples and the Comparative example 1 described above.

x1=0.70 to 1.30

In FIG. 27(b), spectral reflectance characteristics of the formed antireflection coating at each of the measurement positions are shown. As it is understood from these characteristic curves, at the center of the lens surface, the peripheral part of the lens surface, and at a lens surface position therebetween, characteristics are significantly deviated.

More specifically, as it is understood from characteristic curves shown in FIG. 27(b), concerning the antireflection coating formed in Comparative example 2, Δλ1 for reflectance of 1.0% does not exist. Δλ2 for reflectance of 1.0% does not exist either, similarly. In other words, in Comparative example 2, although the antireflection coating is formed by the sputtering method, as it is understood from characteristic curves shown in FIG. 27(b), it is shown that even the spectral reflectance characteristics at the center P may not be formed at a desired value. As is explained above, Comparative example 2 shows that an optical thickness at each of the measurement positions is obviously different, or substantially unequal.

In comparison to this, in Example 6 in which the antireflection coating is formed on the lens surface by the optical thin film forming method in accordance with one embodiment of the present invention, Δλ1 for reflectance of the antireflection coating of 1.0% is 12 nm, and Δλ2 for reflectance of 1.0% is 38 nm, which means that an antireflection coating of a substantially equal optical thickness is formed, and superiority of forming an antireflection coating by the optical thin film forming method in accordance with one embodiment of the present invention may be confirmed.

Comparative example 2 is a comparison with Example 6. Example 6 and Comparative example 2 are the same in terms of the constituent materials and the antireflection coatings being made from a single layer (SiO₂) and they are different in terms of film forming methods.

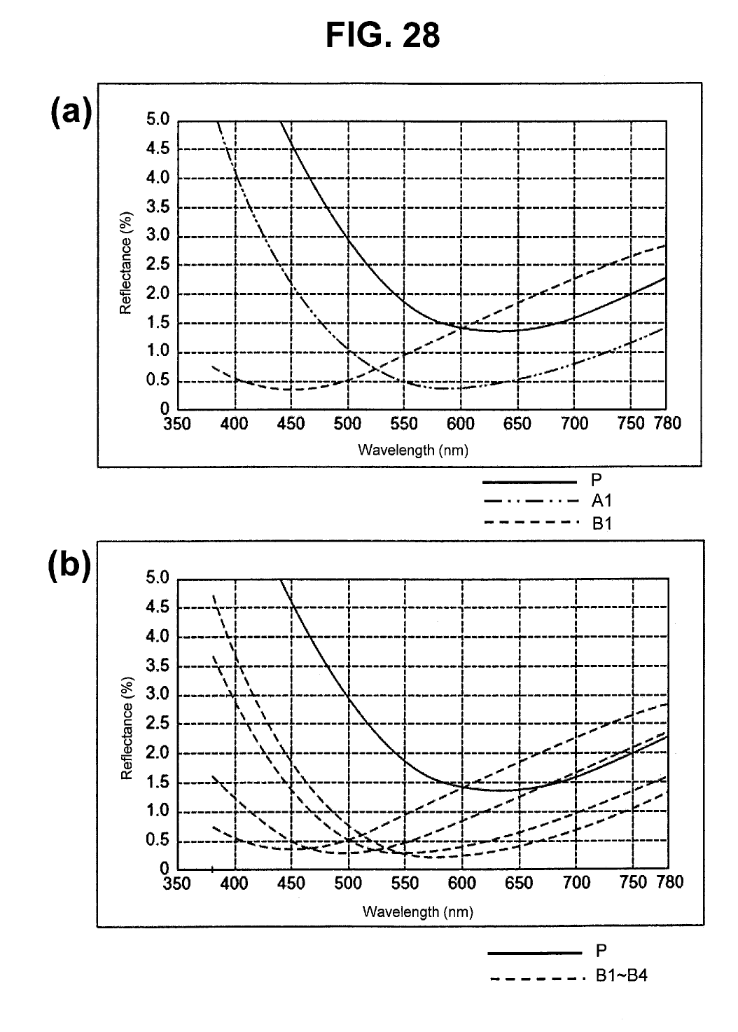

FIG. 28 is diagrams showing spectral reflectance characteristics of the antireflection coating at part of measurement positions on the lens surface of the optical lens that is a target to be deposited in Example 2. FIG. 28(a) is a diagram showing spectral reflectance characteristics at the center P and a plurality of measurement positions A1 and B1 arranged in a radial direction and FIG. 28(b) is a diagram showing spectral reflectance characteristics at the center P and a plurality of measurement positions B1, B2, B3, and B4 arranged in a circumferential direction.

As shown in FIG. 28(a), concerning the antireflection coating formed in Comparative example 2, since Δλ1 for reflectance at the plurality of measurement positions A1 and B1 arranged in the radial direction of 1.0% is obviously larger than 30 nm from FIG. 28(a) and Δλ2 is obviously larger than 55 nm from FIG. 28(a), which means that a variation in an optical thickness of the antireflection coating between the center P and the plurality of measurement position arranged in the radial direction is large. In comparison to this, in Example 6 in which the antireflection coating is formed on the lens surface by the optical thin film forming method in accordance with one embodiment of the present invention, Δλ1 for reflectance at the plurality of measurement positions arranged in the radial direction of the antireflection coating of 1.0% is 2 nm, and Δλ2 for reflectance of 1.0% is 16 nm, which means that an antireflection coating of a substantially equal optical thickness is formed, and superiority of forming an antireflection coating by the optical thin film forming method in accordance with one embodiment of the present invention may be confirmed.

As shown in FIG. 28(b), concerning the antireflection coating formed in Comparative example 2, Δλ1 for reflectance of 1.0% at the plurality of measurement positions B1, B2, B3, and B4 arranged in the circumferential direction is obviously larger than 30 nm from FIG. 28(b) and Δλ2 is obviously larger than 60 nm from FIG. 28(b), which means that a variation in an optical thickness of the antireflection coating between the center P and the plurality of measurement positions arranged in the circumferential direction is large. In comparison to this, in Example 6 in which the antireflection coating is formed on the lens surface of the same shape by the optical thin film forming method in accordance with one embodiment of the present invention, Δλ1 for reflectance at a plurality of measurement positions arranged in the circumferential direction of the antireflection coating of 1.0% is 11 nm, and Δλ2 for reflectance of 1.0% is 30 nm, which means that an antireflection coating of a substantially equal optical thickness is formed, and superiority of forming an antireflection coating by the optical thin film forming method in accordance with one embodiment of the present invention may be confirmed.

In FIG. 27(b), FIG. 28(a) and FIG. 28(b) of Comparative example 2, since the spectral reflectance characteristics at the center P does not have an intersection with reflectance of 1.0%, Δλ1 and Δλ2 are not shown in the diagrams.

As described above, although it is not possible to form an antireflection coating of a substantially equal optical thickness by the conventional sputtering method, it is possible to form an antireflection coating of a substantially equal optical thickness by the optical thin film forming method in accordance with one embodiment of the present invention.

At the end, one embodiment of the present invention is summarized using diagrams and such.

An optical lens 3 in accordance with one embodiment of the present invention includes: an aspherical lens surface 3a formed in a curved shape; and an antireflection coating 14 formed on the aspherical lens surface 3a. The aspherical lens surface 3a includes: a first area including a center P of the aspherical lens surface 3a; and a second area separated from the first area. An optical thickness of an antireflection coating 14 on the first area and an optical thickness of the antireflection coating 14 on the second area are substantially equal.

Here, that the optical thickness of the antireflection coating 14 on the first area and the optical thickness of the antireflection coating 14 on the second area are substantially equal means and that an optical thicknesses (nd) are substantially equal means that light interference is equal, and that optical characteristics such as reflectance, refractive index, and transmittance on the antireflection coating 14 on the first area and the antireflection coating 14 on the second area are substantially equal. In other words, when used as a lens and an optical characteristic distribution is such an extent as not to generate ghost in a photographed image, it may be said that the optical thicknesses are substantially equal. Also, it may be said that, when the antireflection coating 14 on the first area and the antireflection coating 14 on the second area are exchanged, the optical characteristics is substantially equal.

The second area may be a part where, for instance, a surface angle of a curved surface of the optical lens 3 becomes large. For instance, the second area may be an area where a surface angle is 25° or more, and may also be an area where a surface angle is arbitrary such as 28° or more, 30° or more, 40° or more, 48° or more, and 50° or more. The second area may be an area which is preferably substantially equal to the first area as the optical lens 3. The optical lens 3 may be formed so that an optical thickness of the optical thin film at an area having any surface angle is substantially equal to that of the first area.

Preferably, in the optical lens 3, a first wavelength difference Δλ1 between a wavelength at a shortest wavelength side of the antireflection coating 14 formed on the first area (the center P) that satisfies a predetermined reflectance in spectral reflectance characteristics and a wavelength at a shortest wavelength side of the antireflection coating 14 on the second area is 50 nm or less, or a second wavelength difference Δλ2 between a wavelength at a longest wavelength side of the antireflection coating 14 on the first area (the center P) and a wavelength at a longest wavelength side of the antireflection coating 14 on the second area is 100 nm or less.

Further, preferably, in the optical lens 3, when reflectance of 1.0% is satisfied in spectral reflectance characteristics from an ultraviolet area to a near-infrared area, the first wavelength difference Δλ1 is 30 nm or less, or the second wavelength difference Δλ2 is 60 nm or less.

Also, preferably, in the optical lens 3, there are a plurality of second areas, the plurality of second areas include a plurality of areas, for instance, four areas including positions A1 to A4, respectively, arranged in the radial direction of the aspherical lens 3a, and the second wavelength difference Δλ2 for each of the second areas is 60 nm or less.

Also, preferably, in the optical lens 3, there are a plurality of second areas, the plurality of second areas include a plurality of areas, for instance, three areas including positions A1, B1, and C1, respectively, arranged in the circumferential direction of the aspherical lens 3a, and the second wavelength difference Δλ2 for each of the second areas is 60 nm or less.

Also, preferably, in the optical lens 3, the antireflection coating 14 is a single layer film as shown in FIG. 20, and formed of silicon oxide on the surface of the optical lens 3.

Also, preferably, in the optical lens 3, the antireflection coating 14 is a multilayer film as shown in FIG. 5, FIG. 8, FIG. 11, FIG. 14, or FIG. 17.

Also, further, preferably, in the optical lens 3, the antireflection coating 14 is a multilayer film formed on the surface of the optical lens 3 by alternately stacking a layer formed of silicon oxide and a layer formed of niobium oxide as shown in FIG. 5, FIG. 8, FIG. 11, FIG. 14, or FIG. 17.

Also, further it may be understood as follows in another aspect. A reactive sputtering apparatus 1 in accordance with one embodiment of the present invention includes a processing chamber 2, and is an apparatus configured to form an antireflection coating 14 on an optical lens 3 having an aspherical lens surface 3a in the processing chamber 2. The reactive sputtering apparatus 1 includes: an exhaust mechanism 11 configured to exhaust air in the processing chamber 2; an inert gas supply mechanism 12 configured to supply an inert gas into the processing chamber 2 that is retained in a vacuum state; and an active gas supply mechanism 13 configured to supply an active gas into the processing chamber 2 that is retained in a vacuum state. The reactive sputtering apparatus 1 also includes: a workpiece holder 4, provided in the processing chamber 2, on which the optical lens 3 is arranged; and a target 5 arranged opposite to the workpiece holder 4 in the processing chamber 2. The reactive sputtering apparatus 1 further includes: a power supply 7 configured to apply the target 5 with a voltage so that particles of the target 5 emit; and a shielding part 9, provided in the processing chamber 2, configured to be capable of surrounding a specific space 8 which is part of a space in the processing chamber 2 and is a space between the target 5 and the workpiece holder 4.

Preferably, in the reactive sputtering apparatus 1, a position of a lowest part of the shielding part 9 is equal to a highest position of the optical lens 3 arranged on the workpiece holder 4 or lower.

Also, preferably, in the reactive sputtering apparatus 1, the aspherical lens surface 3a has a concave surface shape. In the reactive sputtering apparatus 1, in a state where the optical lens 3 is arranged on the workpiece holder 4, the workpiece holder 4 and the target 5 are arranged so that a value obtained by dividing, by a distance L from the surface of the target 5 to a farthest position of the concave surface shape, a value obtained by further dividing a surface diameter D of a lens surface by a spherical segment length Z of a concave surface shape, falls within a range of 0.010 to 10. In other words, the workpiece holder 4 and the target 5 are arranged in a range of a value calculated by D/Z/L. Preferably, the reactive sputtering apparatus 1 further includes a position change part 15 configured to perform at least one of a first change and a second change. The first change is to change a relative position of the shielding part 9 to the workpiece holder 4 from a first position surrounding the specific space 8 to a second position where the workpiece holder 4 and the shielding part 9 are separated from each other more than in the first position. The second change is to change the relative position from the second position to the first position.

Also, further it may be understood as follows in another aspect. An optical thin film forming method in accordance with one embodiment of the present invention is an antireflection coating forming method for forming an antireflection coating 14 on an optical lens 3 having an aspherical lens surface 3a. The antireflection coating forming method includes: an arrangement step of arranging the optical lens 3 on a workpiece holder 4 in the processing chamber 2; and an exhaust step of evacuating an inside of the processing chamber 2 in a state where the optical lens 3 is arranged in the processing chamber 2. The antireflection coating forming method further includes: a gas supply step of supplying an active gas and an inert gas into the processing chamber 2 after the evacuation; and a sputtering step of extracting particles of a target 5 from the target 5 by applying a voltage to the target 5 arranged opposite to the workpiece holder 4 in a parallel state to cause the inert gas to collide with the target 5. The antireflection coating forming method still further includes: an optical thin film forming step of depositing the target particles obtained by the sputtering step or particles reacting with the active gas on the curved surface of the optical lens 3 in a state where a specific space 8 is surrounded by a shielding part 9.

Also, preferably, in the antireflection coating forming method, in the optical thin film forming step, the optical lens 3 is arranged in an area where Knudsen number, which is obtained by a ratio between a mean free path of the target particles in the specific space 8 and a distance between inside surfaces of the shielding part 9, is less than 0.3.

Also, preferably, in the antireflection coating forming method, the workpiece holder 4 is arranged in reference to the target 5 so that the aspherical lens surface 3a of the optical lens 3 is positioned within a viscous flow domain which is in a state of viscous flow.

Also, it may be understood as follows in another aspect. Concerning an optical lens 3 in accordance with one embodiment of the present invention, at a predetermined reflectance of spectral reflectance of an optical thin film or a predetermined transmittance of spectral transmittance of the optical thin film, a wavelength difference of a wavelength at a shortest wavelength side on a second area in reference to a wavelength at a shortest wavelength side on a first area is ±50 nm or less, or at a predetermined reflectance of the spectral reflectance or at a predetermined transmittance of the spectral transmittance, a wavelength difference of a wavelength at a longest wavelength side on the second area in reference to a wavelength at a longest wavelength side on the first area is ±100 nm or less. Also, further, it may be understood as follows in another aspect. An optical element, or an optical lens 3, in accordance with one embodiment of the present invention includes: a curved surface formed in a curved shape; and an optical thin film formed on the curved surface. The curved surface includes: a first area including a center of the curved surface; and a plurality of second areas that are separated from the first area and are provided by being arranged in a same straight line shape, in a wavelength of a shortest wavelength side at a predetermined reflectance of spectral reflectance of an optical thin film or a predetermined transmittance of spectral transmittance of the optical thin film, a wavelength difference between a first wavelength which is a shortest wavelength on the plurality of second areas and a second wavelength which is a longest wavelength on the plurality of second areas is 30 nm or less, or in a wavelength of a longest wavelength side at a predetermined reflectance of spectral reflectance of an optical thin film or a predetermined transmittance of spectral transmittance of the optical thin film, a wavelength difference between a third wavelength which is a shortest wavelength on the plurality of second areas and a fourth wavelength which is a longest wavelength on the plurality of second areas is 60 nm or less.

Also, further, it may be understood as follows in another aspect. An optical element, or an optical lens 3, in accordance with one embodiment of the present invention includes: a curved surface formed in a curved shape; and an optical thin film formed on the curved surface. The curved surface includes: a first area including a center of the curved surface; and a plurality of second areas that are separated from the first area and are provided by being arranged on the same circumference, in a wavelength of a shortest wavelength side at a predetermined reflectance of spectral reflectance of the optical thin film or a predetermined transmittance of spectral transmittance of the optical thin film, a wavelength difference between a first wavelength which is a shortest wavelength on the plurality of second areas and a second wavelength which is a longest wavelength on the plurality of second areas is 30 nm or less, or in a wavelength of a longest wavelength side at a predetermined reflectance of spectral reflectance of the optical thin film or a predetermined transmittance of spectral transmittance of the optical thin film, a wavelength difference between a third wavelength which is a shortest wavelength on the plurality of second areas and a fourth wavelength which is a longest wavelength on the plurality of second areas is 60 nm or less.

As described above, although one embodiment of the present invention, some Examples, and Comparative examples are described, these are examples for describing the present invention and are not intended to limit a scope of the present invention only to these. In other words, the present invention may be implemented in various forms. For instance, a curved shape may be a free curved shape. A material to be deposited is not limited to an optical element. An optical element is not limited to an optical lens 3. Although a form in which one concave shaped lens surface for one material to be deposited and a land at a peripheral of the lens surface are formed as a material to be deposited is described, a material to be deposited, in which a plurality of concave shaped lens surfaces are formed for one material to be deposited, having a shape of coupling each of the lens surfaces with a land. A surface for a target to be deposited is not limited to a concave surface, and may be a surface composed of curved surfaces and flat surfaces or a surface constituted of a plurality of flat surfaces. Even when a surface to be deposited is a curved surface or a flat surface, an optical thin film of a substantially equal optical thickness may be formed.

Although an example in which an antireflection coating is formed by arranging a lens in a viscous flow domain, an example is not limited to this and an antireflection coating may be formed by arranging a lens in an intermediate flow area. In this case, Knudsen number may be configured in a range of 0.01 to 0.3.

When a material to be deposited is a convex shaped lens, a position of the lowest part of the shielding part may be arranged so as to be at least equal to a lowest position of a lens surface of the convex shaped lens or lower. In one embodiment of the present invention, although the description is made by taking spectral reflectance as an example, an index is not limited to this and the present invention may be applied to spectral transmittance by taking transmittance which has a relation of two sides of the same coin with reflectance as an index.

An optical thin film may be a single layer and a multilayer film. The multilayer film may be of 5 layers, 10 layers, several tens of layers, 100 layers or more.

The present invention may be used for a material to be deposited other than a lens, for instance, such as a curved surface type mirror (a reflection type optical element), a curved surface type filter, an array shaped optical element (a lens array and a prism array) a finder element, a diffraction type optical element, and a Fresnel lens.

### REFERENCE SIGNS LIST

1 Reactive sputtering apparatus
2 Processing chamber
3 Optical lens
3a Lens surface
3b Peripheral edge
3c Land
4 Workpiece holder
4a Workpiece mounting surface
5 Target
5a Target surface
6 Sputtering electrode
7 Power supply
8 Space
9 Shielding part
11 Exhaust mechanism
12 Inert gas supply mechanism
13 Active gas supply mechanism
14 Antireflection coating
L Maximum distance between target surface and lens surface

1. An optical element comprising:
a curved surface formed in a curved shape; and
an optical thin film formed on the curved surface,
wherein the curved surface comprises:
a first area including a center of the curved surface; and
a second area separated from the first area,
wherein an optical thickness of an optical thin film on the first area and an optical thickness of an optical thin film on the second area are substantially equal.

2. The optical element according to claim 1,
wherein, at predetermined reflectance of spectral reflectance of the optical thin film or at predetermined transmittance of spectral transmittance of the optical thin film, a first wavelength difference between a wavelength at a shortest wavelength side on the first area and a wavelength at a shortest wavelength side on the second area is 50 nm or less, or
at predetermined reflectance of spectral reflectance of the optical thin film or at predetermined transmittance of spectral transmittance of the optical thin film, a second wavelength difference between a wavelength at a longest wavelength side on the first area and a wavelength at a longest wavelength side on the second area is 100 nm or less.

3. The optical element according to claim 2,
wherein the optical thin film is an antireflection coating, and
wherein, when spectral reflectance of 1.0% or less is satisfied in spectral reflectance characteristics from an ultraviolet area to a near-infrared area, the first wavelength difference is 30 nm or less, or the second wavelength difference is 60 nm or less.

4. The optical element according to claim 2,
wherein the second area is provided in plurality,
wherein, each of the plurality of second areas are arranged in a radial direction of the curved surface, and
wherein the second wavelength difference is 60 nm or less for each of the plurality of second areas.

5. The optical element according to claim 2,
wherein the second area is provided in plurality,
wherein, each of the plurality of second areas are arranged in a circumferential direction of the curved surface, and
wherein the second wavelength difference is 60 nm or less for each of the plurality of second areas.

6. The optical element according to claim 1,
wherein the optical thin film is a single-layer film, and
wherein the single-layer film is a layer formed of silicon oxide on a surface of the optical element.

7. The optical element according to claim 1,
wherein the optical thin film is a multilayer film.

8. The optical element according to claim 7,
wherein the optical thin film is a multilayer film formed on the surface of the optical element by alternately stacking a layer formed of silicon oxide and a layer formed of niobium oxide.

9. An optical thin film forming apparatus that has a processing chamber and is configured to form an optical thin film on a material to be deposited having a curved surface in the processing chamber, the apparatus comprising:
an exhaust part configured to exhaust air in the processing chamber;
a gas supply part configured to supply an active gas and an inert gas into the processing chamber retained in a vacuum state;
an arrangement part which is provided in the processing chamber and on which the material to be deposited is arranged;
a target arranged opposite to the arrangement part in the processing chamber;
a power supply configured to apply a voltage to the target so that target particles emit; and
a shielding part provided in the processing chamber and configured to be capable of surrounding a specific space, which is part of a space in the processing chamber and is a space between the target and the arrangement part.

10. The optical thin film forming apparatus according to claim 9,
wherein a lowest part position of the shielding part is equal to or lower than a highest position of the material to be deposited arranged on the arrangement part.

11. The optical thin film forming apparatus according to claim 9,
wherein the material to be deposited is an optical element,
wherein the curved surface has a concave surface shape, and
wherein the arrangement part and the target are arranged so that, in a state where the optical element is arranged on the arrangement part, a value obtained by dividing, by a distance from the target surface to a farthest position of the concave surface shape, a value obtained by further dividing a surface diameter of the curved surface by a spherical segment length of the concave surface shape falls within a range of 0.010 to 10.

12. The optical thin film forming apparatus according to claim 9, further comprising a position change part configured to perform at least one of a first change and a second change,
wherein the first change is to distance the shielding part from the arrangement part relatively, and
wherein the second change is to bring the shielding part close to the arrangement part relatively.

13. An optical thin film forming method for forming an optical thin film on a material to be deposited having a curved surface, the method comprising:
an arrangement step of arranging the material to be deposited on an arrangement part in a processing chamber;
an evacuating step of evacuating an inside of the processing chamber in a state where the material to be deposited is arranged in the processing chamber;
a gas supply step of supplying an active gas and an inert gas into the processing chamber after evacuation;
a sputtering step of emitting target particles from a target arranged opposite to the arrangement part by applying a voltage to the target to cause the inert gas to collide with the target; and
an optical thin film forming step of depositing the target particles obtained by the sputtering step or particles reacting with the active gas on the curved surface of the material to be deposited in a state where a specific space that is part of a space in the processing chamber and is a space between the target and the arrangement part is surrounded by a shielding part.

14. The optical thin film forming method according to claim 13,
wherein, in the optical thin film forming step, the material to be deposited is arranged in an area where Knudsen number, which is obtained by a ratio between a mean free path of the target particles in the specific space and a distance between inside surfaces of the shielding part, is less than 0.3.
